(19) United States
(12) Patent Application Publication
(10) Pub. No.: US 2019/0010608 A1
(43) Pub. Date: Jan. 10, 2019

(54) METHOD FOR PRODUCING ELECTROCONDUCTIVE LAMINATE, LAMINATE, AND ELECTROCONDUCTIVE LAMINATE

(71) Applicant: FUJIFILM Corporation, Tokyo (JP)

(72) Inventors: Kohei HIGASHI, Kanagawa (JP); Takehiro KASAHARA, Kanagawa (JP); Daigo MURAI, Kanagawa (JP)

(73) Assignee: FUJIFILM Corporation, Tokyo (JP)

(21) Appl. No.: 16/131,070

(22) Filed: Sep. 14, 2018

Related U.S. Application Data
(63) Continuation of application No. PCT/JP2017/009393, filed on Mar. 9, 2017.

(30) Foreign Application Priority Data
Mar. 31, 2016 (JP) 2016-072363

(51) Int. Cl. C23C 18/20; C23C 18/16; C25D 5/38; H05K 3/18

(52) U.S. Cl. CPC C23C 18/2066; C23C 18/168; C23C 18/1625; C23C 18/1605; C23C 18/1653; C23C 18/1667; H05K 2203/122; H05K 3/185; H05K 3/187; H05K 2203/054; H05K 2203/072; H05K 2203/0723; H05K 2203/0706; C25D 5/38

(57) ABSTRACT

An object of the present invention is to provide a method for producing an electroconductive laminate, which is capable of forming a metal layer having low resistance at a position corresponding to a patterned plated layer, a laminate, and an electroconductive laminate. The method for producing an electroconductive laminate of the present invention includes: a step of forming a plated layer forming layer on a base material using a predetermined plated layer forming composition; a step of subjecting the plated layer forming layer to a patternwise exposure treatment and a development treatment to form a patterned plated layer containing a portion having a line width of less than 3 μm; a step of applying a plating catalyst or a precursor thereof to the patterned plated layer using an alkaline plating catalyst-applying liquid containing the plating catalyst or the precursor thereof; and a step of subjecting the patterned plated layer to which the plating catalyst or the precursor thereof has been applied to a plating treatment using a plating liquid containing aminocarboxylic acids to form a metal layer on the patterned plated layer.

### CROSS-REFERENCE TO RELATED APPLICATIONS

This application is a Continuation of PCT International Application No. PCT/JP2017/009393 filed on Mar. 9, 2017, which claims priority under 35 U.S.C. § 119(a) to Japanese Patent Application No. 2016-072363 filed on Mar. 31, 2016. The above application is hereby expressly incorporated by reference, in its entirety, into the present application.

### BACKGROUND OF THE INVENTION

### 1. Field of the Invention

The present invention relates to a method for producing an electroconductive laminate, a laminate, and an electroconductive laminate.

### 2. Description of the Related Art

An electroconductive film having a conductive layer (electroconductive thin wire) made of a metal or the like formed on a base material has been used for various purposes. Particularly, in recent years, along with an increase in the rate at which a touch panel has been mounted on mobile phones and portable game devices, a demand for an electroconductive film for an electrostatic capacitance touch panel sensor capable of carrying out multi-point detection has been rapidly increasing.

For forming such a conductive layer, for example, a method using a plated layer (underlayer) has been proposed.

For example, JP5756444B discloses a “method for producing a laminate including an underlayer forming step of forming an underlayer containing a polymer having a conjugated diene compound unit which may be hydrogenated and metal oxide particles having an average particle diameter of 400 nm or less, a catalyst applying step of bringing an alkaline plating catalyst liquid containing a plating catalyst or a precursor thereof into contact with the underlayer to apply the plating catalyst or the precursor thereof to the underlayer, and a plating step of subjecting the underlayer, to which the plating catalyst or the precursor thereof has been applied, to plating to form a metal layer on the underlayer” (claim 1).

### SUMMARY OF THE INVENTION

However, the underlayer (plated layer) described in JP5756444B cannot perform pattern formation by photolithography, and there is a problem that the process becomes complicated to form a patterned metal layer.

The present inventors attempted to apply a plating catalyst using an alkaline plating catalyst liquid (plating catalyst-applying liquid) as described in JP5756444B on a patterned plated layer formed into a pattern shape by photolithography, and then attempted to form a metal layer on the patterned plated layer using a plating liquid.

In this case, it was found that the amount of the plating catalyst applied to the patterned plated layer is increased and the metal layer is favorably formed, so that the obtained metal layer could be made low in resistance. However, it was found that depending on the type of the plating liquid, a metal layer is formed also in a region other than the patterned plated layer and then it may be impossible to achieve the formation of a metal layer only at a position corresponding to the patterned plated layer.

Further, as a result of studies by the present inventors, it was found that the resistance of the metal layer to be formed is improved depending on the line width of the patterned plated layer.

Therefore, an object of the present invention is to provide a method for producing an electroconductive laminate, which is capable of forming a metal layer having low resistance at a position corresponding to a patterned plated layer, a laminate, and an electroconductive laminate.

As a result of extensive studies on the foregoing object, the present inventors have found that the desired effect can be obtained by forming a patterned plated layer containing a portion having a line width of less than 3 μm and using an alkaline plating catalyst-applying liquid and a plating liquid containing a predetermined component. The present invention has been completed based on these findings.

That is, the present inventors have found that the foregoing object can be achieved by the following configuration.

[1]

A method for producing an electroconductive laminate having a base material, a patterned plated layer, and a metal layer, the method comprising:

a step of forming a plated layer forming layer on the base material using a plated layer forming composition containing a polymerization initiator and Compound X or Composition Y below;

a step of subjecting the plated layer forming layer to a patternwise exposure treatment and then subjecting the exposed plated layer forming layer to a development treatment to form the patterned plated layer containing a portion having a line width of less than 3 μm;

a step of applying a plating catalyst or a precursor thereof to the patterned plated layer using an alkaline plating catalyst-applying liquid containing the plating catalyst or the precursor thereof; and

a step of subjecting the patterned plated layer to which the plating catalyst or the precursor thereof has been applied to a plating treatment using a plating liquid containing at least one of an aminocarboxylic acid or an aminocarboxylic acid salt to form the metal layer on the patterned plated layer.

Compound X: a compound having a functional group capable of interacting with a plating catalyst or a precursor thereof, and a polymerizable group

Composition Y: a composition containing a compound having a functional group capable of interacting with a plating catalyst or a precursor thereof, and a compound having a polymerizable group

[2]

The method for producing an electroconductive laminate according to [1], in which the plating catalyst or the precursor thereof in the plating catalyst-applying liquid is a metal ion.

[3]

The method for producing an electroconductive laminate according to [1] or [2], in which the interacting functional group is an ionic polar group.

[4]

The method for producing an electroconductive laminate according to any one of [1] to [3], in which the polymerizable group is selected from the group consisting of an acrylamide group and a methacrylamide group.

[5]

The method for producing an electroconductive laminate according to any one of [1] to [4], in which, in the case where the base material is dyed under the dyeing conditions below, a change in absorbance of the base material at a wavelength of 525 nm before and after dyeing is within 0.05.

Dyeing conditions: the base material is immersed in a 0.1 M sodium hydroxide aqueous solution at 30° C. for 5 minutes, and then the base material is taken out and is immersed in a 1% by mass rhodamine 6G aqueous solution for 1 minute

[6]

The method for producing an electroconductive laminate according to any one of [1] to [5], in which the electroconductive laminate is used for a touch panel sensor.

[7]

A laminate comprising:

a base material; and

a patterned plated layer containing a portion having a line width of less than 3 μm and disposed on the base material,

in which a plating catalyst or a precursor thereof is deposited on the patterned plated layer, and the amount of the plating catalyst or the precursor thereof deposited on the patterned plated layer is 50 mg/m² or more.

[8]

An electroconductive laminate comprising:

a base material;

a patterned plated layer containing a portion having a line width of less than 3 μm and disposed on the base material; and

a metal layer disposed on the patterned plated layer,

in which a plating catalyst is deposited on the patterned plated layer, and the amount of the plating catalyst deposited on the patterned plated layer is 50 mg/m² or more.

As will be described hereinafter, according to the present invention, it is possible to provide a method for producing an electroconductive laminate, which is capable of forming a metal layer having low resistance at a position corresponding to a patterned plated layer, a laminate, and an electroconductive laminate.

### BRIEF DESCRIPTION OF THE DRAWINGS

FIG. 1 is a schematic side view for explaining a plated layer forming step in a method for producing an electroconductive laminate of the present invention.

FIG. 2 is a schematic side view for explaining an exposure treatment in a patterned plated layer forming step in the method for producing an electroconductive laminate of the present invention.

FIG. 3 is a schematic side view schematically showing a state in which a mask is removed after the exposure treatment in the patterned plated layer forming step in the method for producing an electroconductive laminate of the present invention.

FIG. 4 is a schematic side view for explaining a development treatment in the patterned plated layer forming step in the method for producing an electroconductive laminate of the present invention.

FIG. 5 is a schematic side view for explaining a plating catalyst applying step in the method for producing an electroconductive laminate of the present invention.

FIG. 6 is a schematic side view for explaining a metal layer forming step in the method for producing an electroconductive laminate of the present invention.

FIG. 7 is a schematic plan view in the case where an electroconductive laminate obtained by the method for producing an electroconductive laminate of the present invention is applied to a touch panel sensor.

### DESCRIPTION OF THE PREFERRED EMBODIMENTS

The present invention will be described below.

In the present invention, the numerical range expressed by using “to” means a range including numerical values described before and after “to” as a lower limit value and an upper limit value, respectively.

[Method for Producing Electroconductive Laminate]

The method for producing an electroconductive laminate of the present invention is a method for producing an electroconductive laminate having a base material, a patterned plated layer, and a metal layer.

Further, the method for producing an electroconductive laminate of the present invention includes

a step of forming a plated layer forming layer on the base material using a plated layer forming composition containing a polymerization initiator and Compound X or Composition Y which will be described later (hereinafter, also referred to as “plated layer forming step”);

a step of subjecting the plated layer forming layer to a patternwise exposure treatment and then subjecting the exposed plated layer forming layer to a development treatment to form the patterned plated layer containing a portion having a line width of less than 3 μm (hereinafter, also referred to as “patterned plated layer forming step”);

a step of applying a plating catalyst or a precursor thereof to the patterned plated layer using an alkaline plating catalyst-applying liquid containing the plating catalyst or the precursor thereof (hereinafter, also referred to as “plating catalyst applying step”); and

a step of subjecting the patterned plated layer to which the plating catalyst or the precursor thereof has been applied to a plating treatment using a plating liquid containing at least one of an aminocarboxylic acid or an aminocarboxylic acid salt to form the metal layer on the patterned plated layer (hereinafter, also referred to as “metal layer forming step”).

According to the method for producing an electroconductive laminate of the present invention, it is possible to form a metal layer having low resistance at a position corresponding to a patterned plated layer. Although the details of this reason have not been elucidated yet, it is presumed to be due to the following reasons.

It is considered that, in the case where the alkaline plating catalyst-applying liquid is used, the patterned plated layer swells well and therefore the permeability of the plating catalyst-applying liquid is improved. As a result, it is presumed that the amount of the plating catalyst or the precursor thereof applied to the patterned plated layer increased, and therefore a metal layer having low resistance could be formed.

Further, in the case where the patterned plated layer is treated with the alkaline plating catalyst-applying liquid (that is, in the case where the amount of the plating catalyst applied to the patterned plated layer is large) as described above, a metal layer can be formed at a position corresponding to the patterned plated layer in the case where a plating liquid containing at least one of an aminocarboxylic acid or an aminocarboxylic acid salt is used.

Although the details of this reason have not been elucidated, it is presumed to be due to the following reasons.

As a plating liquid, a Rochelle salt-based plating liquid (for example, an electroless plating liquid THRU-CUP PEA (trade name, manufactured by C. Uyemura & Co., Ltd.) described in paragraph [0101] of the above-mentioned JP5756444B) may be used. As a result of studies by the present inventors, it was found that, in the case where the plating treatment with a Rochelle salt-based plating liquid was interrupted for a short time (the early stage of plating deposition), the pattern selectivity (formation of a metal layer only at the position corresponding to the patterned plated layer) is not improved. From this, it is speculated that the plating liquid of Rochelle salt-based plating liquid is designed so as to cover the entire surface of the plating object cleanly even though the deposition rate is slow. In other words, since the Rochelle salt-based plating liquid is a liquid designed pursuing a throwing power, it is speculated that it is at the expense of pattern selectivity (formation of a metal layer at a position corresponding to the patterned plated layer).

On the other hand, the present inventors have found that, in the case where the plating liquid of the present invention containing at least one of an aminocarboxylic acid or an aminocarboxylic acid salt is used, pattern selectivity is excellent in the case where a plating treatment is interrupted in a short time and pattern selectivity can be maintained even in the case where the plating treatment time is prolonged.

For this reason, the plating liquid of the present invention containing at least one of an aminocarboxylic acid or an aminocarboxylic acid salt is presumed to have relatively higher pattern selectivity as compared with the above-mentioned Rochelle salt-based plating liquid.

Further, the present inventors have found that, in the case where the line width of the patterned plated layer exceeds a predetermined value, the resistance of the metal layer to be formed increases.

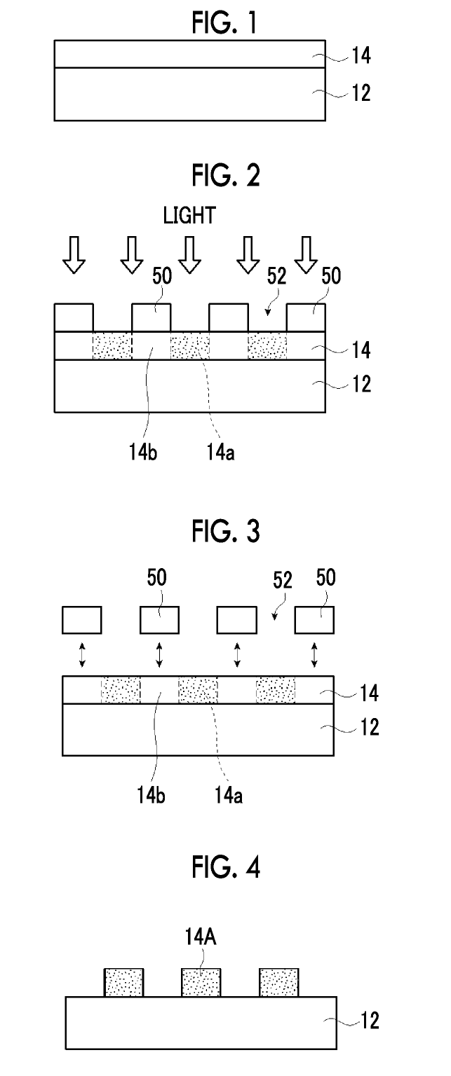

Hereinafter, the method for producing an electroconductive laminate of the present invention will be described for each step with reference to FIGS. 1 to 6. FIGS. 1 to 6 are schematic side views showing step by step an example of the method for producing an electroconductive laminate of the present invention.

[Plated Layer Forming Step]

The plated layer forming step is a step of forming a plated layer forming layer on the base material using a plated layer forming composition containing a polymerization initiator, and Compound X or Composition Y which will be described later.

FIG. 1 is a schematic side view for explaining the plated layer forming step, and shows a state in which a plated layer forming layer 14 is disposed on (directly above) a base material 12.

In the example of FIG. 1, the plated layer forming layer 14 is provided on the entire surface of the base material 12, but the present invention is not limited thereto, and the plated layer forming layer 14 may be formed in a part of the surface of the base material 12.

The type of the base material 12 is not particularly limited and may be, for example, an insulating base material. More specifically, a resin base material, a ceramic base material, a glass base material, or the like can be used.

The thickness (mm) of the base material 12 is not particularly limited, but is preferably 0.01 to 1 mm and more preferably 0.02 to 0.1 mm from the viewpoint of the balance of handleability and thickness reduction.

Further, the base material 12 preferably transmits light appropriately. Specifically, the total light transmittance of the base material 12 is preferably 85% to 100%.

The base material 12 may be a sheet shape (single sheet) or an elongated shape (continuous body).

The base material may have a single layer structure or a multilayer structure.

The base material 12 may have a support and a primer layer disposed on the support. As the support, materials constituting the above-mentioned base materials can be mentioned.

The primer layer is positioned on the outermost surface of the support (the surface on which the patterned plated layer forming layer to be described later is formed). As a result, the adhesiveness of the plated layer forming layer (patterned plated layer) to the base material is improved.

The thickness of the primer layer is not particularly limited. Generally, the thickness of the primer layer is preferably 0.01 to 100 μm, more preferably 0.05 to 20 μm, and still more preferably 0.05 to 10 μm.

The material for the primer layer is not particularly limited, but it is preferably a resin having good adhesiveness with a base material. A specific example of the resin may be a thermosetting resin, a thermoplastic resin, or a mixture thereof. Examples of the thermosetting resin include an epoxy resin, a phenol resin, a polyimide resin, a polyester resin, a bismaleimide resin, a polyolefin-based resin, and an isocyanate-based resin. Examples of the thermoplastic resin include a phenoxy resin, polyether sulfone, polysulfone, polyphenylene sulfone, polyphenylene sulfide, polyphenyl ether, polyether imide, and an ABS resin (acrylonitrile-butadiene-styrene copolymer).

The thermoplastic resins and the thermosetting resins may be respectively used alone or in combination of two or more thereof. Further, a resin containing a cyano group may be used. Specifically, an ABS resin, and “polymers containing a unit having a cyano group on the side chain” described in paragraphs [0039] to [0063] of JP2010-84196A may also be used.

Further, it may also be possible to use a rubber component such as acrylonitrile-butadiene rubber (NBR rubber) or styrene-butadiene rubber (SBR rubber).

As one suitable aspect of the material constituting the primer layer, a urethane resin can be mentioned.

The urethane resin may be, for example, a reaction product of a diol compound and a diisocyanate compound.

Examples of the diol compound include diols such as ethylene glycol, propylene glycol, 1,2-propanediol, 1,3-propanediol, 1,3-butanediol, 1,4-butanediol, neopentyl glycol, 1,5-pentanediol, 1,6-hexanediol, 3-methylpentanediol, diethylene glycol, 1,4-cyclohexanedimethanol, 3-methyl-1,5-pentanediol, 2-methyl-1,3-propanediol, 2,2-diethyl-1,3-propanediol, 2-butyl-2-ethyl-1,3-propanediol, xylylene glycol, hydrogenated bisphenol A or bisphenol A, and polyalkylene glycol. Also, alkylene oxide adducts of these compounds (for example, an ethylene oxide adduct and a propylene oxide adduct) can be mentioned.

Among them, polyalkylene glycol is preferable and polyethylene glycol, polypropylene glycol, or polytetramethylene glycol is more preferable, from the viewpoint of easily adjusting the surface hardness and the friction coefficient with release paper in a predetermined range. The average addition molar number of the oxyalkylene in the polyalkylene glycol is preferably 3 to 20. The weight-average molecular weight of the polyalkylene glycol is preferably 100 to 2,000.

The diol compounds may be used alone or in combination of two or more thereof.

Examples of the diisocyanate compound include an aromatic diisocyanate compound such as 2,4-tolylene diisocyanate, a dimer of 2,4-tolylene diisocyanate, 2,6-tolylene diisocyanate, p-xylylene diisocyanate, m-xylylene diisocyanate, 4,4′-diphenylmethane diisocyanate, 1,5-naphthylene diisocyanate, or 3,3′-dimethylbiphenyl-4,4′-diisocyanate; an aliphatic diisocyanate compound such as hexamethylene diisocyanate, trimethylhexamethylene diisocyanate, lysine diisocyanate, or dimer acid diisocyanate; and an alicyclic diisocyanate compound such as isophorone diisocyanate, 4,4′-methylene bis(cyclohexylisocyanate), methylcyclohexane-2,4 (or 2,6)diisocyanate, or 1,3-(isocyanatomethyl)cyclohexane. Among these, an aliphatic diisocyanate compound such as isophorone diisocyanate or hexamethane diisocyanate is preferable from the viewpoint of high transparency of the cured product.

The diisocyanate compounds may be used alone or in combination of two or more thereof.

The urethane resin is synthesized, for example, by adding and heating the diisocyanate compound and the diol compound, and a known catalyst in an aprotic solvent. The molar ratio of the diisocyanate and diol compounds used in the synthesis is not particularly limited and may be appropriately selected depending on the purpose. It is preferably 1:1.2 to 1.2:1.

A photocurable material may be used as the urethane resin. As the photocurable urethane resin, it is preferable to use a urethane (meth)acrylate synthesized from a diisocyanate compound, a diol compound, and a hydroxyalkyl (meth)acrylate. Among them, from the viewpoint of easily adjusting the surface hardness and the friction coefficient with release paper in a predetermined range, preferred is urethane di(meth)acrylate, and particularly preferred is a urethane di(meth)acrylate oligomer having a weight-average molecular weight range to be described later.

The (meth)acrylate means acrylate or methacrylate. Examples of the diisocyanate compound and the diol compound include the above-mentioned compounds, and preferred aspects thereof are also the same.

Examples of the hydroxyalkyl (meth)acrylate include hydroxyl group-containing (meth)acrylate such as hydroxyethyl (meth)acrylate (for example, 2-hydroxyethyl (meth)acrylate), hydroxypropyl (meth)acrylate (for example, 2-hydroxypropyl (meth)acrylate), hydroxybutyl (meth)acrylate (for example, 2-hydroxybutyl (meth)acrylate), hydroxybutyl (meth)acrylate (for example, 4-hydroxybutyl (meth)acrylate), hydroxyhexyl (meth)acrylate (for example, 6-hydroxyhexyl (meth)acrylate), or pentaerythritol tri(meth)acrylate; a hydroxyl group-containing (meth)acrylate-modified product represented by a caprolactone-modified product or alkyl oxide-modified product thereof; and an addition reaction product of a monoepoxy compound such as butyl glycidyl ether, 2-ethylhexyl glycidyl ether, or glycidyl (meth)acrylate with (meth)acrylic acid. Among them, hydroxyethyl (meth)acrylate or hydroxybutyl (meth)acrylate is preferable from the viewpoint of easily adjusting the surface hardness and the friction coefficient with release paper in a predetermined range.

The hydroxyalkyl (meth)acrylates may be used alone or in combination of two or more thereof.

In addition, in the case of synthesizing urethane (meth)acrylate, a component (for example, a reactive diluted monomer) other than the foregoing components may be further contained as a raw material component.

Examples of the reactive diluted monomer include an alicyclic (meth)acrylate such as isobornyl (meth)acrylate or cyclohexyl (meth)acrylate; and an aromatic (meth)acrylate such as phenoxyethyl (meth)acrylate.

The reactive diluted monomers may be used alone or in combination of two or more thereof.

The urethane (meth)acrylate can be produced by a known method. For example, the urethane (meth)acrylate can be synthesized in such a manner that a diol compound is added to a diisocyanate compound, the mixture is reacted at 50° C. to 80° C. for about 3 to 10 hours, a hydroxyalkyl (meth)acrylate, an optional reactive diluted monomer, a catalyst such as dibutyltin dilaurate, and a polymerization inhibitor such as methylhydroquinone are added thereto, and the mixture is further reacted at 60° C. to 70° C. for 3 to 12 hours.

The ratio of the diisocyanate compound, the diol compound, and the hydroxyalkyl (meth)acrylate used is not particularly limited as long as the desired surface hardness and friction coefficient with release paper are achieved, but it is preferable such that 0.9≤(total number of isocyanate groups in diisocyanate compound)/(total number of hydroxyl groups in diol compound and hydroxyalkyl (meth)acrylate)≤1.1.

From the viewpoint of easily adjusting the surface hardness and the friction coefficient with release paper in a predetermined range, the weight-average molecular weight of the urethane (meth)acrylate is preferably 5,000 or more and 120,000 or less, more preferably 15,000 or more and 80,000 or less, and still more preferably 30,000 or more and 70,000 or less in terms of polystyrene measured by a gel permeation chromatography (GPC) method.

One suitable aspect of the material constituting a primer layer may be, for example, a polymer having a conjugated diene compound unit which may be hydrogenated. The conjugated diene compound unit refers to a repeating unit derived from a conjugated diene compound. The conjugated diene compound is not particularly limited as long as it is a compound having a molecular structure having two carbon-carbon double bonds separated by one single bond.

One suitable aspect of the repeating unit derived from a conjugated diene compound may be, for example, a repeating unit generated by a polymerization reaction of a compound having a butadiene skeleton.

The conjugated diene compound unit may be hydrogenated, and in the case of containing a hydrogenated conjugated diene compound unit, adhesiveness of a metal layer is preferably further improved. That is, the double bond in the repeating unit derived from a conjugated diene compound may be hydrogenated.

The polymer having a conjugated diene compound unit which may be hydrogenated may also contain the interactive group which will be described hereinafter.

Examples of suitable aspects of this polymer include an acrylonitrile butadiene rubber (NBR), a carboxyl group-containing nitrile rubber (XNBR), an acrylonitrile-butadiene-isoprene rubber (NBIR), an ABS resin, and a hydrogenated product thereof (for example, a hydrogenated acrylonitrile butadiene rubber).

The primer layer may also contain other additives (for example, a sensitizer, an antioxidant, an antistatic agent, an ultraviolet absorber, a filler, particles, a flame retardant, a surfactant, a lubricant, and a plasticizer).

In the base material of the present invention, it is preferred that the change in absorbance at 525 nm of the base material before and after dyeing is within 0.05 in the case of being dyed under the dyeing conditions below. By using the base material having such properties, damage to the base material in the plating catalyst applying step to be described below can be reduced.

Dyeing conditions: the base material is immersed in a 0.1 M sodium hydroxide aqueous solution at 30° C. for 5 minutes, and then the base material is taken out and is immersed in a 1% by mass rhodamine 6G aqueous solution for 1 minute.

Examples of the base material having such properties include a hydrogenated acrylonitrile butadiene rubber (H-NBR) and a urethane resin.

Here, the absorbance of the base material before and after dyeing can be measured using a device according to a spectrophotometer V-670 (trade name, manufactured by JASCO Corporation).

A method for forming the plated layer forming layer 14 on the base material 12 is not particularly limited, and a known method (for example, bar coating, spin coating, die coating, or dip coating) can be used.

From the viewpoint of handleability and production efficiency, after the plated layer forming composition is applied, a drying treatment may be carried out as necessary to remove the residual solvent.

The conditions of the drying treatment are not particularly limited, but from the viewpoint of superior productivity, it is preferable to carry out the drying treatment at room temperature (20° C.) to 220° C. (preferably 50° C. to 120° C.) for 1 to 30 minutes (preferably 1 to 10 minutes).

The thickness of the plated layer forming layer is not particularly limited, but it is preferably 0.05 to 5 μm, more preferably 0.1 to 1 μm, and still more preferably 0.2 to 0.7 μm.

The thickness of the plated layer forming layer is an average thickness, and is a value obtained by measuring thicknesses of any 10 points of the plated layer forming layer and arithmetically averaging the measured values.

<Plated Layer Forming Composition>

The plated layer forming layer is formed using a plated layer forming composition containing a polymerization initiator and Compound X or Composition Y below. Hereinafter, the components which are contained in the plated layer forming composition and the components which may be contained in the plated layer forming composition will be described in detail.

Compound X: a compound having a functional group capable of interacting with a plating catalyst or a precursor thereof (hereinafter, also simply referred to as “interactive group”), and a polymerizable group

Composition Y: a composition containing a compound having a functional group capable of interacting with a plating catalyst or a precursor thereof, and a compound having a polymerizable group

(Compound X)

Compound X is a compound having an interactive group and a polymerizable group.

The interactive group is intended to refer to a functional group capable of interacting a plating catalyst or a precursor thereof which is applied to a patterned plated layer. For example, a functional group capable of forming an electrostatic interaction with a plating catalyst or a precursor thereof, or a nitrogen-, sulfur- or oxygen-containing functional group capable of coordinating with a plating catalyst and a precursor thereof may be used.

More specific examples of the interactive group include nitrogen-containing functional groups such as an amino group, an amide group, an imido group, a urea group, a tertiary amino group, an ammonium group, an amidino group, a triazine ring, a triazole ring, a benzotriazole group, an imidazole group, a benzimidazole group, a quinoline group, a pyridine group, a pyrimidine group, a pyrazine group, a nazoline group, a quinoxaline group, a purine group, a triazine group, a piperidine group, a piperazine group, a pyrrolidine group, a pyrazole group, an aniline group, a group containing an alkylamine structure, a group containing an isocyanuric structure, a nitro group, a nitroso group, an azo group, a diazo group, an azide group, a cyano group, and a cyanate group; oxygen-containing functional groups such as an ether group, a hydroxyl group, a phenolic hydroxyl group, a carboxy group, a carbonate group, a carbonyl group, an ester group, a group containing an N-oxide structure, a group containing an S-oxide structure, and a group containing an N-hydroxy structure; sulfur-containing functional groups such as a thiophene group, a thiol group, a thiourea group, a thiocyanurate group, a benzothiazole group, a mercaptotriazine group, a thioether group, a thioxy group, a sulfoxide group, a sulfone group, a sulfite group, a group containing a sulfoximine structure, a group containing a sulfoxonium salt structure, a sulfonate group, and a group containing a sulfonic ester structure; phosphorus-containing functional groups such as a phosphate group, a phosphoramide group, a phosphine group, and a group containing a phosphoric ester structure; and groups containing halogen atoms such as chlorine and bromine. In a functional group that may have a salt structure, a salt thereof may also be used.

Among them, preferred is an ionic polar group such as a carboxy group, a sulfonate group, a phosphate group or a boronate group, an ether group, or a cyano group, and more preferred is an ionic polar group.

In the case where the patterned plated layer has an ionic polar group, the ionic polar group tends to be present as ions in the alkaline plating catalyst-applying liquid. As a result, it is presumed that the permeability of the plating catalyst-applying liquid to the patterned plated layer is further improved since the patterned plated layer is rendered hydrophilic.

Compound X may contain two or more interactive groups.

The polymerizable group is a functional group capable of forming a chemical bond through the application of energy, and examples thereof include a radically polymerizable group and a cationic polymerizable group. Among them, a radically polymerizable group is preferable from the viewpoint of superior reactivity.

Examples of the radically polymerizable group include unsaturated carboxylic ester groups such as an acrylic ester group (acryloyloxy group), methacrylic ester group (methacryloyloxy group), an itaconic ester group, a crotonic ester group, an isocrotonic ester group, and a maleic ester group; a styryl group, a vinyl group, an acrylamide group, and an methacrylamide group. Among them, preferred is a methacryloyloxy group, an acryloyloxy group, a vinyl group, a styryl group, an acrylamide group, or methacrylamide group; more preferred is a methacryloyloxy group, an acryloyloxy group, a styryl group, an acrylamide group, or a methacrylamide group; and still more preferred is an acrylamide group or a methacrylamide group.

The compound X may contain two or more polymerizable groups. The number of the polymerizable groups contained in the compound X is not particularly limited and may be one or two or more.

Compound X may be a low molecular weight compound or a high molecular weight compound. The low molecular weight compound is intended to refer to a compound having a molecular weight of less than 1,000, and the high molecular weight compound is intended to refer to a compound having a molecular weight of 1,000 or more.

Further, the low molecular weight compound having a polymerizable group corresponds to a so-called monomer. Further, the high molecular weight compound may be a polymer having a predetermined repeating unit.

Further, the compounds may be used alone or in combination of two or more thereof.

In the case where Compound X is a polymer, the weight-average molecular weight of the polymer is not particularly limited and is preferably 1,000 or more and 700,000 or less and more preferably 2,000 or more and 200,000 or less, from the viewpoint that handleability such as solubility is superior. In particular, the weight-average molecular weight is preferably 20,000 or more from the viewpoint of polymerization sensitivity.

The method of synthesizing such a polymer having a polymerizable group and an interactive group is not particularly limited and a known synthesis method (see paragraphs to [0125] of JP2009-280905A) is used.

The weight-average molecular weight in the present invention is measured by gel permeation chromatography (GPC).

The GPC uses HLC-8220 GPC (manufactured by Tosoh Corporation), TSKgel G5000PW_{XL}, TSKgel G4000PW_{XL}, TSKgel G2500PW_{XL} (manufactured by Tosoh Corporation, 7.8 mmID×30 cm) as columns, and a 10 mM NaNO₃ aqueous solution as an eluent. In addition, regarding conditions, the GPC is carried out using an RI (differential refraction) detector with a sample concentration of 0.1% by mass, a flow rate of 1.0 ml/min (reference: 0.5 ml/min), a sample injection volume of 100 μl, and a measurement temperature of 40□C.

In addition, the calibration curve is made from TSK standard POLY(ETHYLENE OXIDE): “SE-150”, “SE-30”, “SE-8”, “SE-5”, and “SE-2” (manufactured by Tosoh Corporation), polyethylene glycol having a molecular weight of 3,000, and hexaethylene glycol having a molecular weight of 282.

(Suitable Aspect 1 of Polymer)

A first preferred aspect of the polymer may be, for example, a copolymer containing a polymerizable group-containing repeating unit represented by Formula (a) (hereinafter, also referred to as a “polymerizable group unit” where appropriate) and an interactive group-containing repeating unit represented by Formula (b) (hereinafter, also referred to as an “interactive group unit” where appropriate).

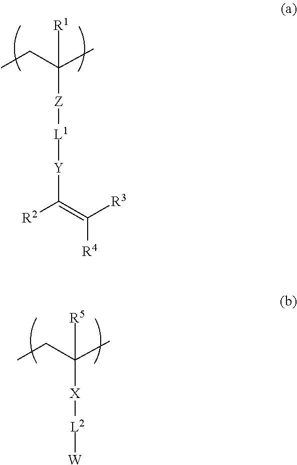

In Formulae (a) and (b), R¹ to R⁵ each independently represent a hydrogen atom, or a substituted or unsubstituted alkyl group (for example, a methyl group, an ethyl group, a propyl group, or a butyl group). Further, the type of the substituent is not particularly limited, and examples thereof include a methoxy group, a chlorine atom, a bromine atom, and a fluorine atom.

R¹ is preferably a hydrogen atom, a methyl group, or a methyl group substituted with a bromine atom. R² is preferably a hydrogen atom, a methyl group, or a methyl group substituted with a bromine atom. R³ is preferably a hydrogen atom. R⁴ is preferably a hydrogen atom. R⁵ is preferably a hydrogen atom, a methyl group, or a methyl group substituted with a bromine atom.

In Formulae (a) and (b), X, Y, and Z each independently represent a single bond, or a substituted or unsubstituted divalent organic group. Examples of the divalent organic group include a substituted or unsubstituted divalent aliphatic hydrocarbon group (which preferably contains 1 to 8 carbon atoms. For example, an alkylene group such as a methylene group, an ethylene group, or a propylene group), a substituted or unsubstituted divalent aromatic hydrocarbon group (which preferably contains 6 to 12 carbon atoms. For example, a phenylene group), —O—, —S—, —SO₂—, —N(R)— (R: alkyl group), —CO—, —NH—, —COO—, —CONH—, and a group formed by combining these groups (for example, an alkyleneoxy group, an alkyleneoxycarbonyl group, or an alkylenecarbonyloxy group).

X, Y, and Z are each preferably a single bond, an ester group (—COO—), an amide group (—CONH—), an ether group (—O—), or a substituted or unsubstituted divalent aromatic hydrocarbon group and more preferably a single bond, an ester group (—COO—), or an amide group (—CONH—), from the viewpoint of easy polymer synthesis and superior adhesiveness of a metal layer.

In Formulae (a) and (b), L¹ and L² each independently represent a single bond, or a substituted or unsubstituted divalent organic group. The divalent organic group has the same definition as in the divalent organic group described for X, Y, and Z above.

L¹ is preferably an aliphatic hydrocarbon group or a divalent organic group (for example, an aliphatic hydrocarbon group) having a urethane bond or a urea bond from the viewpoint of easy polymer synthesis and superior adhesiveness of a metal layer. Among them, preferred are groups having a total number of carbon atoms of 1 to 9. The total number of carbon atoms in L¹ refers to the total number of carbon atoms contained in the substituted or unsubstituted divalent organic group represented by L¹.

Further, L² is preferably a single bond, a divalent aliphatic hydrocarbon group, a divalent aromatic hydrocarbon group, or a group formed by combining these groups, from the viewpoint of superior adhesiveness of a metal layer. Among them, L² is preferably a single bond or has a total number of carbon atoms of 1 to 15 and is particularly preferably unsubstituted. Here, the total number of carbon atoms in L² refers to a total number of carbon atoms contained in the substituted or unsubstituted divalent organic group represented by L².

In Formula (b), W represents an interactive group. The definition of the interactive group is as described above.

The content of the polymerizable group unit is preferably 5 to 50 mol % and more preferably 5 to 40 mol % with respect to the total repeating units in the polymer, from the viewpoint of reactivity (curability or polymerizability) and inhibition of gelation during synthesis.

Further, the content of the interactive group unit is preferably 5 to 95 mol % and more preferably 10 to 95 mol % with respect to the total repeating units in the polymer, from the viewpoint of adsorptivity to a plating catalyst or a precursor thereof.

(Suitable Aspect 2 of Polymer)

The second preferred aspect of the polymer may be, for example, a copolymer containing repeating units represented by Formula (A), Formula (B), and Formula (C).

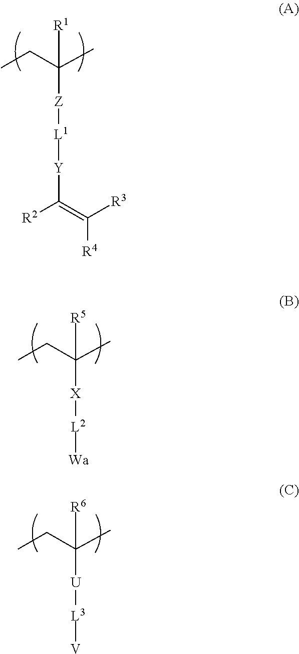

The repeating unit represented by Formula (A) is the same as the repeating unit represented by Formula (a), and the same also applies to the description of each group.

R⁵, X, and L² in the repeating unit represented by Formula (B) is the same as R⁵, X, and L² in the repeating unit represented by Formula (b), and the same also applies to the description of each group.

Wa in Formula (B) represents a group capable of interacting with a plating catalyst or a precursor thereof, excluding a hydrophilic group or a precursor group thereof represented by V to be described hereinafter. Among them, preferred is a cyano group or an ether group.

In Formula (C), R⁶'s each independently represent a hydrogen atom or a substituted or unsubstituted alkyl group.

In Formula (C), U represents a single bond or a substituted or unsubstituted divalent organic group. The definition of the divalent organic group is the same as that of the above-mentioned divalent organic group represented by X, Y, and Z. U is preferably a single bond, an ester group (—COO—), an amide group (—CONH—), an ether group (—O—), or a substituted or unsubstituted divalent aromatic hydrocarbon group, from the viewpoint of easy polymer synthesis and superior adhesiveness of a metal layer.

In Formula (C), L³ represents a single bond or a substituted or unsubstituted divalent organic group. The definition of the divalent organic group is the same as that of the above-mentioned divalent organic group represented by L¹ and L². L³ is preferably a single bond, or a divalent aliphatic hydrocarbon group, a divalent aromatic hydrocarbon group, or a group formed by combining these groups, from the viewpoint of easy polymer synthesis and superior adhesiveness of a metal layer.

In Formula (C), V represents a hydrophilic group or a precursor group thereof. The hydrophilic group is not particularly limited as long as it is a group exhibiting hydrophilicity, and examples thereof include a hydroxyl group and a carboxy group. The precursor group of the hydrophilic group refers to a group capable of generating a hydrophilic group by a predetermined treatment (for example, treatment with an acid or alkali), and examples thereof include a carboxy group protected with a 2-tetrahydropyranyl (THP) group.

The hydrophilic group is preferably an ionic polar group from the viewpoint of interaction with a plating catalyst or a precursor thereof. Specific examples of the ionic polar group include a carboxy group, a sulfonate group, a phosphate group, and a boronate group. Among them, preferred is a carboxy group from the viewpoint of moderate acidity (not degrading other functional groups).

The preferred content of each unit in the second preferred aspect of the polymer is as follows.

The content of the repeating unit represented by Formula (A) is preferably 5 to 50 mol % and more preferably 5 to 30 mol % with respect to the total repeating units in the polymer, from the viewpoint of reactivity (curability or polymerizability) and inhibition of gelation during synthesis.

The content of the repeating unit represented by Formula (B) is preferably 5 to 75 mol % and more preferably 10 to 70 mol % with respect to the total repeating units in the polymer, from the viewpoint of adsorptivity to a plating catalyst or a precursor thereof.

The content of the repeating unit represented by Formula (C) is preferably 10 to 70 mol %, more preferably 20 to 60 mol %, and still more preferably 30 to 50 mol % with respect to the total repeating units in the polymer, from the viewpoint of developability with an aqueous solution and humidity-resistant adhesiveness.

Specific examples of the above-mentioned polymer include polymers described in paragraphs [0106] to [0112] of JP2009-007540A, polymers described in paragraphs [0065] to [0070] of JP2006-135271A, and polymers described in paragraphs [0030] to [0108] of US2010-080964A.

These polymers can be produced by known methods (for example, methods in the literature listed above).

(Suitable Aspect of Monomer)

In the case where the compound is a so-called monomer, a compound represented by Formula (X) can be mentioned as one suitable aspect.

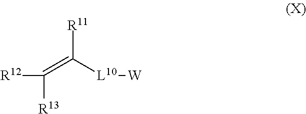

In Formula (X), R¹¹ to R¹³ each independently represent a hydrogen atom or a substituted or unsubstituted alkyl group. Examples of the unsubstituted alkyl group include a methyl group, an ethyl group, a propyl group, and a butyl group. Examples of the substituted alkyl group include a methyl group, an ethyl group, a propyl group, and a butyl group each of which is substituted with a methoxy group, a chlorine atom, a bromine atom, a fluorine atom, or the like. R¹¹ is preferably a hydrogen atom or a methyl group. R¹² is preferably a hydrogen atom. R¹³ is preferably a hydrogen atom.

L¹⁰ represents a single bond or a divalent organic group. Examples of the divalent organic group include a substituted or unsubstituted aliphatic hydrocarbon group (preferably having 1 to 8 carbon atoms), a substituted or unsubstituted aromatic hydrocarbon group (preferably having 6 to 12 carbon atoms), —O—, —S—, —SO₂—, —N(R)— (R: alkyl group), —CO—, —NH—, —COO—, —CONH—, and a group formed by combining these groups (for example, an alkyleneoxy group, an alkyleneoxycarbonyl group, or an alkylenecarbonyloxy group).

The substituted or unsubstituted aliphatic hydrocarbon group is preferably a methylene group, an ethylene group, a propylene group or a butylene group, or a group in which such a group is substituted with a methoxy group, a chlorine atom, a bromine atom, a fluorine atom, or the like.

The substituted or unsubstituted aromatic hydrocarbon group is preferably an unsubstituted phenylene group, or a phenylene group substituted with a methoxy group, a chlorine atom, a bromine atom, a fluorine atom, or the like.

In Formula (X), one suitable aspect of L¹⁰ may be, for example, a —NH-aliphatic hydrocarbon group- or a —CO-aliphatic hydrocarbon group-.

W has the same definition as W in Formula (b) and represents an interactive group. The definition of the interactive group is as described above.

In Formula (X), a suitable aspect of W may be, for example, an ionic polar group and is more preferably a carboxy group.

In the case where the above-mentioned compound is a so-called monomer, a compound represented by Formula (1) may be mentioned as one of other suitable aspects.

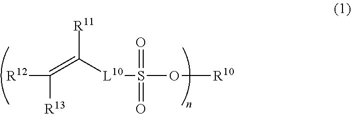

In Formula (1), R¹⁰ represents a hydrogen atom, a metal cation, or a quaternary ammonium cation. Examples of the metal cation include an alkali metal cation (a sodium ion or a calcium ion), a copper ion, a palladium ion, and a silver ion. Further, a monovalent or divalent metal cation is generally used as the metal cation. In the case where the divalent metal cation (for example, a palladium ion) is used, n to be described hereinafter represents 2.

Examples of the quaternary ammonium cation include a tetramethyl ammonium ion and a tetrabutyl ammonium ion.

Among them, preferred is a hydrogen atom from the viewpoint of adhesion of a plating catalyst or a precursor thereof, and metal residues after patterning.

L¹⁰ in Formula (1) has the same definition of L¹⁰ in Formula (X) and represents a single bond or a divalent organic group. The definition of the divalent organic group is as described above.

R¹¹ to R¹³ in Formula (1) have the same definition of R¹¹ to R¹³ in Formula (X) and represent a hydrogen atom or a substituted or unsubstituted alkyl group. Suitable aspects of R¹¹ to R¹³ are as described above.

n represents an integer of 1 or 2. n is preferably 1 from the viewpoint of availability of the compound.

A compound represented by Formula (2) may be mentioned as a suitable aspect of the compound represented by Formula (1).

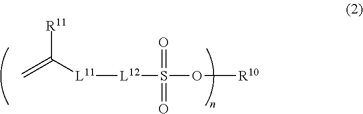

In Formula (2), R¹⁰, R¹¹, and n are as defined above.

L¹¹ represents an ester group (—COO—), an amide group (—CONH—), or a phenylene group. Among them, if L¹¹ is an amide group, solvent resistance (for example, alkali solvent resistance) is improved.

L¹² represents a single bond, a divalent aliphatic hydrocarbon group (preferably having 1 to 8 carbon atoms, and more preferably having 3 to 5 carbon atoms), or a divalent aromatic hydrocarbon group. The aliphatic hydrocarbon group may be linear, branched, or cyclic. In the case where L¹² is a single bond, L¹¹ represents a phenylene group.

The molecular weight of the compound represented by Formula (1) is not particularly limited, but it is preferably 100 to 1,000 and more preferably 100 to 300 from the viewpoint of volatility, solubility in a solvent, film forming properties, and handleability.

(Composition Y)

The composition Y is a composition containing a compound having an interactive group and a compound having a polymerizable group. That is, the plated layer forming layer contains two compounds: a compound having an interactive group and a compound having a polymerizable group. The definition of the interactive group and the polymerizable group is as described above.

The compound having an interactive group is a compound having an interactive group. The definition of the interactive group is as described above. Such a compound may be a low molecular weight compound or a high molecular weight compound. A suitable aspect of the compound having an interactive group may be, for example, a polymer having a repeating unit represented by Formula (b) as described above (for example, polyacrylic acid). Further, a polymerizable group is not contained in the compound having an interactive group.

The compound having a polymerizable group is a so-called monomer, and is preferably a polyfunctional monomer having two or more polymerizable groups from the viewpoint of superior hardness of a patterned plated layer which will be formed. With regard to the polyfunctional monomer, specifically, it is preferred to use a monomer having 2 to 6 polymerizable groups. From the viewpoint of mobility of molecules during the crosslinking reaction which affects the reactivity, the molecular weight of the polyfunctional monomer to be used is preferably 150 to 1,000 and more preferably 200 to 800. Further, the interval (distance) between a plurality of polymerizable groups is preferably 1 to 15 atoms.

The compound having a polymerizable group may contain an interactive group.

One suitable form of the compound having a polymerizable group may be, for example, a compound represented by Formula (1).

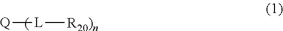

In Formula (1), R₂₀ represents a polymerizable group. The definition of the polymerizable group is as described above.

L represents a single bond or a divalent organic group. The definition of the divalent organic group is as described above.

Q represents an n-valent organic group. Preferred examples of the n-valent organic group include a group represented by Formula (1A), a group represented by Formula (1B),

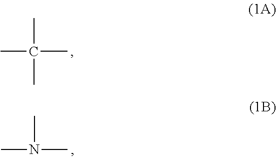

—NH—, —NR (R: alkyl group)-, —O—, —S—, a carbonyl group, an alkylene group, an alkenylene group, an alkynylene group, a cycloalkylene group, an aromatic group, a heterocyclic group, and an n-valent organic group formed by combining two or more of these groups.

n represents an integer of 2 or more and preferably 2 to 6.

Among the foregoing polyfunctional monomers, polyfunctional (meth)acrylamide is preferably used from the viewpoint that the hardness of the patterned plated layer to be formed is superior.

The polyfunctional (meth)acrylamide is not particularly limited as long as it has 2 or more (preferably 2 to 6) (meth)acrylamide groups.

Among the polyfunctional (meth)acrylamides, tetrafunctional (meth)acrylamide represented by General Formula (A) can be used more preferably from the viewpoint of excellent curing rate of the plated layer forming layer.

In the present invention, the (meth)acrylamide is a concept including both acrylamide and methacrylamide.

The tetrafunctional (meth)acrylamide represented by General Formula (A) can be produced, for example, by the production method described in JP5486536B.

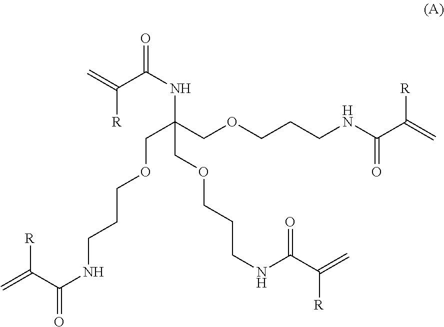

In General Formula (A), R represents a hydrogen atom or a methyl group. General Formula (A), a plurality of R's may be the same as or different from each other.

The mass ratio of the compound having an interactive group and the compound having a polymerizable group (mass of the compound having an interactive group/mass of the compound having a polymerizable group) is not particularly limited, but it is preferably 0.1 to 10 and more preferably 0.5 to 5 in terms of balance of strength of a plated layer to be formed and plating suitability.

The content of Compound X (or Composition Y) is not particularly limited, but it is preferably 50% by mass or more and more preferably 80% by mass or more with respect to 100% by mass of the total solid content in the plated layer forming composition. The upper limit thereof is not particularly limited, but it is preferably 99.5% by mass or less.

(Polymerization Initiator)

The plated layer forming composition contains a polymerization initiator. By including the polymerization initiator, the reaction between the polymerizable groups during the exposure treatment more efficiently proceeds.

The polymerization initiator is not particularly limited, and a known polymerization initiator (so-called photopolymerization initiator) or the like can be used. Examples of the polymerization initiator include benzophenones, acetophenones, α-aminoalkylphenones, benzoins, ketones, thioxanthones, benzyls, benzyl ketals, oxime esters, anthrones, tetramethylthiuram monosulfides, bisacylphosphine oxides, acylphosphine oxides, anthraquinones, azo compounds, and derivatives thereof.

The content of the polymerization initiator is not particularly limited, but from the viewpoint of the curability of the plated layer, the content of the polymerization initiator is preferably 0.1% to 20% by mass and more preferably 0.5% to 10% by mass, with respect to 100% by mass of the compound having a polymerizable group in the plated layer forming composition.

(Surfactant)

The plated layer forming composition of the present invention preferably contains a surfactant. Thereby, due to the action of the surfactant contained in the plated layer forming layer, removal of the mask after the exposure treatment can be easily carried out, and adhesion of a part of the plated layer forming layer to the mask can also be suppressed. Further, since contamination of the mask can be suppressed, there is also a process advantage that the number of washing times of the mask can be reduced or washing of the mask can be eliminated.

Various surfactants such as a fluorine-based surfactant, a nonionic surfactant, a cationic surfactant, an anionic surfactant, and a silicone-based surfactant can be used as the surfactant. Among them, a fluorine-based surfactant or a silicone-based surfactant is preferable and a fluorine-based surfactant is more preferable from the viewpoint that the above-mentioned effects are further exerted. The surfactants may be used alone or in combination of two or more thereof.

Examples of the fluorine-based surfactant include W-AHE and W-AHI (both of which are manufactured by FUJIFILM Corporation), MEGAFACE F171, F172, F173, F176, F177, F141, F142, F143, F144, R30, F437, F475, F479, F482, F554, F780, and F781F (all of which are manufactured by DIC Corporation), FLUORAD FC430, FC431, and FC171 (all of which are manufactured by Sumitomo 3M Limited), SURFLON S-382, SC-101, SC-103, SC-104, SC-105, SC1068, SC-381, SC-383, 5393, and KH-40 (all of which are manufactured by Asahi Glass Co., Ltd.), and PF636, PF656, PF6320, PF6520, and PF7002 (all of which are OMNOVA Solutions Inc.).

Commercially available products can be used as the silicone-based surfactant, and examples thereof include TORAY SILICONE DC3PA, SH7PA, DC11PA, SH21PA, SH28PA, SH29PA, SH30PA, and SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP341, KF6001, and KF6002 (all of which are manufactured by Shin-Etsu Silicone Co., Ltd.), and BYK307, BYK323, and BYK330 (all of which are manufactured by BYK-Chemie GmbH).

In the case where the plated layer forming composition contains a surfactant, the content of the surfactant is preferably 0.005% to 0.5% by mass, more preferably 0.01% to 0.1% by mass, and still more preferably 0.01% to 0.05% by mass, with respect to the total amount of 100% by mass of the plated layer forming composition.

The plated layer forming composition may contain other additives (for example, an organic solvent, a sensitizer, a curing agent, a polymerization inhibitor, an antioxidant, an antistatic agent, a filler, a particle, a flame retardant, a lubricant, and a plasticizer) as required.

In particular, in the case of containing an organic solvent, from the viewpoint that the functions of the silicone-based surfactant and the fluorine-based surfactant among the foregoing surfactants are further exerted, the solvent is preferably a hydrophilic solvent such as isopropanol or propylene glycol-1-monomethylether-2-acetate.

[Patterned Plated Layer Forming Step]

The patterned plated layer forming step is a step of subjecting the plated layer forming layer to a patternwise exposure treatment and then subjecting the exposed plated layer forming layer to a development treatment to form the patterned plated layer containing a portion having a line width of less than 3 μm.

<Exposure Treatment>

The exposure treatment method is not particularly limited, and for example, there is a method of irradiating the plated layer forming layer with exposure light through a mask.

FIG. 2 is a schematic side view showing an example of an exposure treatment for the plated layer forming layer 14. As shown in FIG. 2, the plated layer forming layer 14 has an exposed region (exposed portion) 14a which is a portion irradiated with light passing through an opening portion 52 of a mask 50 by the exposure treatment, and an unexposed region (unexposed portion) 14b which is a portion not irradiated with light.

Such an exposure treatment method is preferably a step of bringing the plated layer forming layer and the mask into close contact with each other under vacuum and subjecting the plated layer forming layer to a patternwise exposure treatment. As a result, the pattern accuracy of the patterned plated layer to be formed becomes excellent (that is, a patterned plated layer corresponding to the opening portion size of the mask is obtained). In addition to the above-mentioned effects, there is also an advantage that oxygen inhibition during polymerization of the plated layer forming layer can be reduced and therefore a patterned plated layer having excellent curability can be obtained.

As a method of bringing the plated layer forming layer and the mask into close contact with each other under vacuum, for example, it is possible to use a device having a known vacuum mechanism (for example, a vacuum pump such as a rotary pump).

Here, the term “vacuum” is a concept including a negative pressure indicating a state in which the pressure is lower than the standard atmospheric pressure. Specifically, the pressure during vacuum is preferably 200 Pa or less, more preferably 150 Pa or less, and still more preferably 0.01 to 100 Pa.

In the exposure treatment, exposure with light having an optimum wavelength is carried out according to the material of the plated layer forming layer 14 to be used, but for example, an irradiation apparatus or the like provided with a light irradiation mechanism by an ultraviolet (UV) lamp, visible light, or the like is used. Examples of the light source include a mercury lamp, a metal halide lamp, a xenon lamp, a chemical lamp, and a carbon arc lamp. Further, electron beams, X-rays, ion beams, far infrared rays, or the like can also be used.

As a light irradiation mechanism used for the exposure treatment, it is preferable to use a parallel light exposure machine from the viewpoint that the pattern accuracy of the plated layer forming layer to be formed is further improved.

The wavelength of light irradiated in the exposure treatment is preferably 300 nm or shorter and more preferably 200 to 270 nm, from the viewpoint that a finer pattern can be formed.

The exposure time varies depending on the reactivity of the material of the plated layer forming layer and the light source, but it is usually between 10 seconds and 5 hours. The exposure energy may be about 10 to 8,000 mJ and preferably 50 to 3,000 mJ.

The type of the mask 50 is not particularly limited, and for example, known masks such as a glass mask (such as a chromium mask whose glass surface is covered with a chromium film, or an emulsion mask whose glass surface is coated with a film containing gelatin and silver halide) and a film mask (polyester film) can be used.

The method for producing an electroconductive laminate of the present invention may include a step of removing the mask after the exposure treatment.

FIG. 3 is a schematic side view showing a state in which the mask 50 is removed after the exposure treatment and before the development treatment which will be described later. The example of FIG. 3 shows the case where the removal of the mask 50 is carried out before the development treatment which will be described later, but the present invention is not limited thereto, and the removal of the mask 50 may be carried out simultaneously with the development treatment or after the development treatment.

<Development Treatment>

The development treatment is carried out after the exposure treatment. Thereby, a patterned plated layer is formed.

The method of development treatment is not particularly limited, and examples thereof include a method of immersing the plated layer forming layer after the exposure treatment in a developer (an alkaline solution, an organic solvent, or the like) and a method of applying a developer onto the surface of the plated layer forming layer, among which a method of immersion is preferable.

In the case of the immersion method, the immersion time is preferably about 1 minute to 30 minutes from the viewpoint of productivity and workability.

FIG. 4 is a schematic side view showing an example of a state in which the patterned plated layer 14A is formed by the development treatment.

The example of FIG. 4 shows the case where the development treatment is a treatment of removing the unexposed portion 14b (see FIG. 3) of the plated layer forming layer 14. As a result, the exposed portion 14a is patterned to obtain the patterned plated layer 14A having the same shape as the opening portion 52 of the pattern. As described above, the example of FIG. 4 shows the case where the plated layer forming layer 14 is formed using a so-called negative tone plated layer forming composition.

The example of FIG. 4 shows the case where the development treatment removes the unexposed portion 14b, but contrary to this, the development treatment may remove the exposed portion 14a to leave the unexposed portion 14b. That is, the plated layer forming layer 14 is formed using a so-called positive tone plated layer forming composition.

<Line Width and the Like of Patterned Plated Layer>

The patterned plated layer obtained as described above contains a portion having a line width of less than 3 μm, and preferably contains a portion having a line width of 1 μm or more and less than 3 μm.

It is preferred that the line width of the patterned plated layer is narrow in a region where transparency or visibility (metal wiring is not visible) is required, and it is more preferred that the line width in such a region is 1 μm or more and less than 3 μm.

The line width of the patterned plated layer refers to a width of the patterned plated layer in a direction orthogonal to the direction in which the wiring extends in the case where the metal layer formed on the patterned plated layer is a wiring pattern (such as a lead-out wiring to be described later) and in the case where the wiring pattern is viewed in plan.

The contact angle of the surface of the patterned plated layer 14A obtained as described above is preferably 90° to 120°, more preferably 100° to 120°, and still more preferably 105° to 120°. In the case where the contact angle is within the above range, the peeling property from the mask 50 after the exposure treatment can be improved, and adhesion of the plated layer forming layer 14 to the mask 50 can be suppressed.

In the present invention, the contact angle of the patterned plated layer refers to a contact angle with water, and it is measured by a tangent method as a measuring method.

[Plating Catalyst Applying Step]

The plating catalyst applying step is a step of applying a plating catalyst or a precursor thereof to the patterned plated layer using an alkaline plating catalyst-applying liquid containing the plating catalyst or the precursor thereof.

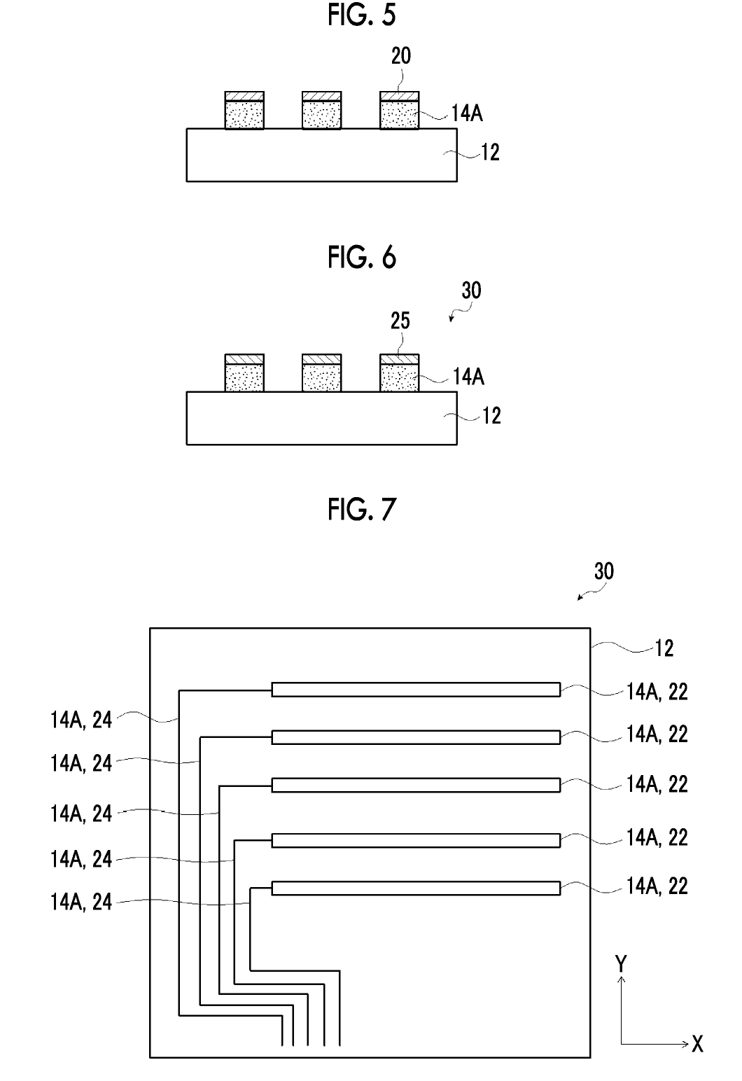

By carrying out the present step, as shown in FIG. 5, a layer 20 of a plating catalyst or a precursor thereof (hereinafter, also simply referred to as “plating catalyst layer”) is formed on the patterned plated layer 14A.

The example of FIG. 5 shows the case where the plating catalyst layer 20 is formed only on the upper surface of the patterned plated layer 14A, but the present invention is not limited thereto, and the plating catalyst layer 20 may be formed on the upper surface and the side surface of the patterned plated layer 14A (that is, the entire surface of the patterned plated layer 14A).

In the present step, a plating catalyst or a precursor thereof is applied onto a patterned plated layer. The above-mentioned interactive group contained in the patterned plated layer adheres to (adsorbs) the applied plating catalyst or precursor thereof, according to the function thereof. More specifically, the plating catalyst or the precursor thereof is applied on the surface of the patterned plated layer.

The plating catalyst or the precursor thereof functions as a catalyst or electrode of a plating treatment. Therefore, the type of the plating catalyst or the precursor thereof to be used is appropriately determined depending on the type of the plating treatment.

<Plating Catalyst-Applying Liquid>

The application of the plating catalyst or the precursor thereof is carried out using an alkaline plating catalyst-applying liquid containing a plating catalyst or a precursor thereof. Thereby, the plating catalyst or the precursor thereof and the patterned plated layer come into contact with each other.

Examples of the method of applying the plating catalyst or the precursor thereof include a method in which a plating catalyst-applying liquid is applied onto a patterned plated layer and a method in which a laminate on which a patterned plated layer has been formed is immersed in a plating catalyst-applying liquid.

The contact time between the plating catalyst-applying liquid and the patterned plated layer is preferably about 30 seconds to 24 hours, and more preferably about 1 minute to 1 hour.

(Plating Catalyst or Precursor Thereof)

As the plating catalyst or the precursor thereof, an electroless plating catalyst can be preferably used.

Any electroless plating catalyst may be used as long as it serves as an active nucleus at the time of electroless plating. Specifically, a metal having a catalytic capacity of the autocatalytic reduction reaction (which is known as a metal capable of electroless plating with lower ionization tendency than Ni) may be used. Specific examples thereof include Pd, Ag, Cu, Ni, Pt, Au, and Co. Among them, preferred is Ag, Pd, Pt, or Cu from the viewpoint of high catalytic capacity.

Any electroless plating catalyst precursor can be used without particular limitation as long as it may be converted into an electroless plating catalyst by a chemical reaction. Metal ions of the metals illustrated above for the electroless plating catalyst are mainly used. The metal ions which are the electroless plating catalyst precursors are converted by the reduction reaction into zero-valent metals which are the electroless plating catalysts. After the metal ion as the electroless plating catalyst precursor is applied to the patterned plated layer, the electroless plating catalyst precursor may be converted into a zero-valent metal as the electroless plating catalyst by a separate reduction reaction before being immersed in an electroless plating bath. Alternatively, the electroless plating catalyst precursor may be immersed in the electroless plating bath without any treatment to be converted into a metal (electroless plating catalyst) by the action of a reducing agent in the electroless plating bath.

A metal salt is preferably used to apply the metal ion as the electroless plating catalyst precursor to the patterned plated layer. The metal salt used is not particularly limited as long as it dissolves in a suitable solvent to be dissociated into a metal ion and a base (anion). Examples thereof include M(NO₃)ₙ, MClₙ, M_{2/n}(SO₄), and M_{3/n}(PO₄) (where M represents an n-valent metal atom). The metal ion resulting from the dissociation of the metal salt may be suitably used. Examples of the metal ion include Ag ion, Cu ion, Ni ion, Co ion, Pt ion, and Pd ion. Among them, ions capable of multidentate coordination are preferred. Particularly, Ag ion, Pd ion, or Cu ion is preferred from the viewpoint of the number of types of functional groups capable of coordination and the catalytic capacity.

In the present step, a zero-valent metal may be used as the catalyst used for carrying out direct electroplating without electroless plating.

The plating catalyst or the precursor thereof may be a metallic colloid or a metal ion in the plating catalyst-applying liquid, but it is preferably a metal ion from the viewpoint that the plating catalyst or the precursor thereof is likely to be applied to a position corresponding to the patterned plated layer.

The concentration of the plating catalyst or the precursor thereof in the plating catalyst-applying liquid is not particularly limited, but it is preferably 0.001% to 50% by mass and more preferably 0.005% to 30% by mass.

(Solvent)

The plating catalyst-applying liquid preferably contains a solvent. The solvent is not particularly limited as long as it can disperse or dissolve the plating catalyst or the precursor thereof, and for example, water and/or an organic solvent can be preferably used.

The organic solvent is preferably a solvent capable of permeating the patterned plated layer. For example, acetone, methyl acetoacetate, ethyl acetoacetate, ethylene glycol diacetate, cyclohexanone, acetylacetone, acetophenone, 2-(1-cyclohexenyl)cyclohexanone, propylene glycol diacetate, triacetin, diethylene glycol diacetate, dioxane, N-methylpyrrolidone, dimethyl carbonate, or dimethyl cellosolve may be used.

The plating catalyst-applying liquid may contain a swelling agent, a surfactant, a pH adjusting agent, and the like, if necessary.

The plating catalyst-applying liquid shows alkalinity (pH of more than 7), but the pH thereof is preferably 9 or more and more preferably 10 or more. The upper limit value of the pH is not particularly limited, but it is preferably 13 or less from the viewpoint that the damage of the patterned plated layer can be reduced.

By using a pH adjusting agent such as sodium hydroxide or potassium hydroxide, for example, the plating catalyst-applying liquid can be easily adjusted to have a desired pH.

The pH in the present invention is measured by using a device according to a pH meter F-74 (trade name, manufactured by Horiba, Ltd.) with the temperature of the plating catalyst-applying liquid set at 25° C.

[Metal Layer Forming Step]

The metal layer forming step is a step of subjecting the patterned plated layer to which the plating catalyst or the precursor thereof has been applied to a plating treatment using a plating liquid containing at least one of an aminocarboxylic acid or an aminocarboxylic acid salt to form the metal layer on the patterned plated layer.

By carrying out the present step, as shown in FIG. 6, the metal layer 25 is formed on the patterned plated layer 14A. In this manner, the metal layer 25 is formed at a position corresponding to the plating catalyst layer 20. Therefore, in the case where the plating catalyst layer 20 is formed on the upper surface and the side surface (that is, the entire surface of the patterned plated layer 14A) of the patterned plated layer 14A, the metal layer 25 is formed on the entire surface of the patterned plated layer 14A.

The method of a plating treatment is not particularly limited, and examples thereof include an electroless plating treatment and an electrolytic plating treatment (electroplating treatment). In the present step, an electroless plating treatment may be carried out alone, or an electrolytic plating treatment may be further carried out following an electroless plating treatment.

In the present specification, a so-called silver mirror reaction is included as one type of the above-mentioned electroless plating treatment. Thus, a desired metal layer may be formed by reducing the deposited metal ions, for example, by a silver mirror reaction or the like, and thereafter an electrolytic plating treatment may be further carried out.

Hereinafter, the procedure of the electroless plating treatment and electrolytic plating treatment will be described in detail.

The electroless plating treatment refers to an operation of depositing metals through a chemical reaction using a solution of metal ions to be deposited as plating dissolved therein (a plating liquid to be described later).

For example, the electroless plating in the present step is preferably carried out in such a manner that a laminate having the patterned plated layer to which an electroless plating catalyst has been applied is washed with water to remove an excess of the electroless plating catalyst (metal), and then immersed in an electroless plating bath (a plating liquid to be described later). As the electroless plating bath to be used, a known electroless plating bath may be employed. The immersion time in the electroless plating bath is preferably about 1 minute to 6 hours, and more preferably about 1 minute to 3 hours. The temperature of the electroless plating bath is preferably 25° C. to 70° C.

Further, in the case where a base material having the patterned plated layer to which an electroless plating catalyst precursor has been applied is immersed in an electroless plating bath in a state of an electroless plating catalyst precursor being adsorbed or impregnated in the patterned plated layer, it is preferred that a laminate is washed with water to remove an excess of the electroless plating catalyst precursor (such as a metal salt), and then immersed in the electroless plating bath. In this case, the reduction of the electroless plating catalyst precursor and subsequently the electroless plating are carried out in the electroless plating bath. Also with respect to the electroless plating bath used herein, a known electroless plating bath may be employed in the same manner as described above.

Further, apart from the aspect of using an electroless plating bath as described above, the reduction of an electroless plating catalyst precursor can also be carried out with the preparation of a catalyst activating liquid (reducing liquid), as a separate step prior to electroless plating.

<Plating Liquid>

It is preferred that the plating liquid used in the metal layer forming step in the method for producing an electroconductive laminate of the present invention contains at least one of an aminocarboxylic acid or an aminocarboxylic acid salt and further contains a metal ion for plating and a solvent.

(Aminocarboxylic Acid and Aminocarboxylic Acid Salt)

The plating liquid contains at least one of an aminocarboxylic acid or an aminocarboxylic acid salt. Here, the aminocarboxylic acid refers to a compound having an amino group and a carboxy group. The amino group may be any one of a primary amino group, a secondary amino group, and a tertiary amino group.

Examples of the aminocarboxylic acid and aminocarboxylic acid salt include glycine, ethylenediaminetetraacetic acid, hydroxyethylethylenediaminetriacetic acid, diethylenetriaminepentaacetic acid, triethylenetetraminehexaacetic acid, nitrilotriacetic acid, hydroxyethyliminodiacetic acid, L-aspartic acid-N,N-diacetic acid, hydroxyiminodisuccinic acid, and salts thereof.

The aminocarboxylic acids and the aminocarboxylic acid salts may be used alone or in combination of two or more thereof.

The content of the aminocarboxylic acid and the aminocarboxylic acid salt is preferably 0.5% to 5% by mass and more preferably 1.5% to 3% by mass with respect to 100% by mass of the total mass of the plating liquid.

(Metal Ion for Plating)

It is preferred that the plating liquid contains a metal ion for plating. The metal ion for plating exists as an ion in the plating liquid by adding a metal to the plating liquid.

Examples of the metal to be added to the plating liquid include copper, tin, lead, nickel, gold, silver, palladium, and rhodium, among which copper, silver, or gold is preferred and copper is more preferred from the viewpoint of conductivity.

The concentration of the metal ion for plating in the plating liquid is not particularly limited, but it is preferably 0.1% to 5% by mass and more preferably 0.5% to 1.5% by mass.

(Solvent)

The plating liquid preferably contains a solvent. Examples of the solvent include water and an organic solvent.

The organic solvent is preferably a water-soluble solvent. Specifically, ketones such as acetone and alcohols such as methanol, ethanol, and isopropanol are preferably used.

The solvents may be used alone or in combination of two or more thereof.

(Other Components)

In addition to the above components, the plating liquid may contain known additives such as a reducing agent and an additive (stabilizer) for improving the stability of a metal ion.

In the metal layer forming step, in the case where a plating catalyst or a precursor thereof that has been applied to the patterned plated layer functions as an electrode, electroplating can be carried out on the patterned plated layer to which the catalyst or the precursor thereof has been applied.

As described above, in the present step, if necessary, an electroplating treatment may be carried out after the electroless plating treatment. In such an aspect, the thickness of a metal layer to be formed is appropriately adjustable.

Any method known in the related art may be used for electroplating. Examples of the metal that may be used in electroplating include copper, chromium, lead, nickel, gold, silver, tin, and zinc. From the viewpoint of conductivity, copper, gold, or silver is preferred and copper is more preferred.

<Line Width and the Like of Metal Layer>

In the present invention, since a metal layer is formed on the patterned plated layer obtained by the above-described method, it is possible to form a low-resistance fine metal pattern at a desired position. Specifically, the line width of the metal layer is preferably 0.1 to 10 μm and more preferably 0.5 to 5 μm.

Here, the line width of the metal layer refers to a width of the wiring in a direction orthogonal to the direction in which the wiring extends, for example, in the case where the metal layer formed on the patterned plated layer is a wiring pattern (such as a lead-out wiring to be described later) and in the case where the wiring pattern is viewed in plan.

The line width of the metal layer can be controlled by the plating treatment time, the concentration of metal ions in the plating liquid, the plating liquid temperature, and the like.

The thickness of the metal layer can be controlled by the plating treatment time, the concentration of metal ions in the plating liquid, the plating liquid temperature, and the like. For example, the thickness of the metal layer is preferably 0.2 to 2 μm and more preferably 0.4 to 1 μm.

In the example of FIG. 6, the patterned plated layer 14A and the metal layer 25 are formed on one surface of the base material 12, but the present invention is not limited thereto, and the patterned plated layer 14A and the metal layer 25 may be formed on the other surface of the base material 12. In this case as well, these layers can be formed in the same manner as the above-mentioned method.

[Applications]

The electroconductive laminate obtained by the method for producing an electroconductive laminate of the present invention can be applied to various uses and can be applied to various applications such as a touch panel (or a touch panel sensor), a semiconductor chip, various electric wiring boards, a flexible printed circuit (FPC), a chip on film (COF), a tape automated bonding (TAB), an antenna, a multilayer wiring board, and a main board. Among them, it is preferable to use such a laminate for a touch panel sensor (electrostatic capacitance touch panel sensor). In the case where the electroconductive laminate is applied to a touch panel sensor, the metal layer in the electroconductive laminate functions as a detection electrode or a lead-out wiring in the touch panel sensor.

In the present specification, a combination of a touch panel sensor and various display devices (for example, a liquid crystal display device and an organic electroluminescence (EL) display device) is called a touch panel. The touch panel is preferably, for example, a so-called electrostatic capacitance touch panel.

FIG. 7 shows an embodiment in the case where the electroconductive laminate obtained by the method for producing an electroconductive laminate of the present invention is applied to a touch panel sensor.

As shown in FIG. 7, the electroconductive laminate 30 includes the patterned plated layer 14A disposed on the base material 12, and the detection electrode 22 and the lead-out wiring 24 disposed on the patterned plated layer 14A. The detection electrode 22 and the lead-out wiring 24 are formed of the above-described metal layer.

In order to produce such an electroconductive laminate 30, the patterned plated layer 14A is formed at a position where the detection electrode 22 and the lead-out wiring 24 are desired to be disposed, and a metal layer is formed thereon. That is, the patterned plated layer 14A is disposed between the detection electrode 22 and the lead-out wiring 24, and the base material 12.

In the case where the touch panel sensor including this metal layer-containing laminate is incorporated as a member of the touch panel, the detection electrode 22 functions as a sensing electrode that senses a change in the electrostatic capacitance, and constitutes a sensing portion.

The detection electrode 22 has a function of detecting an input position in the X direction of the finger of the operator approaching the input region of the touch panel sensor and has a function of generating an electrostatic capacitance between the fingers. The detection electrode 22 is an electrode extending in a first direction (X direction) and disposed at a predetermined interval in a second direction (Y direction) orthogonal to the first direction.

The lead-out wiring 24 is a member that plays a role of applying a voltage to the detection electrode 22.

[Laminate]

The laminate of the present invention has a base material and a patterned plated layer containing a portion having a line width of less than 3 μm and disposed on the base material, in which a plating catalyst or a precursor thereof is deposited on the patterned plated layer, and the deposited amount of the plating catalyst or the precursor thereof in the patterned plated layer is 50 mg/m² or more.

The laminate of the present invention is obtained by carrying out in the order of a plated layer forming step, a patterned plated layer forming step, and a plating catalyst applying step in the above-described method for producing an electroconductive laminate. That is, the laminate of the present invention is produced without carrying out the metal layer forming step in the above-described method for producing an electroconductive laminate. In the case of using the laminate of the present invention, a metal layer having low resistance can be formed at a position corresponding to the patterned plated layer.

The details of the base material, the patterned plated layer, and the plating catalyst or the precursor thereof included in the laminate of the present invention are the same as described in the method for producing an electroconductive laminate, so that the description thereof will be omitted.

Since the laminate of the present invention is obtained by the above-described method, the deposited amount of the plating catalyst or the precursor thereof becomes a high value of 50 mg/m² or more. Accordingly, in the case of forming a metal layer on the patterned plated layer of the laminate, initial uniformity of plating (uniform formation of the metal layer on the plated layer at the beginning of the metal layer forming step) is improved, and as a result, conduction can be secured even in a state in which the thickness of the plating film is thin, so that a fine wiring with good conduction is formed.

In the laminate of the present invention, the deposited amount of the plating catalyst or the precursor thereof is 50 mg/m² or more and preferably 50 to 1,000 mg/m².

In the present invention, the deposited amount of the plating catalyst or the precursor thereof is measured using a glow discharge optical emission spectrometer (GD-OES). Specifically, a value obtained by integrating the counts of the signals derived from the plating catalyst or the precursor thereof in the depth direction on the patterned plated layer to which the plating catalyst or the precursor thereof is deposited by using a glow discharge optical emission spectrometer is divided by the area of the measurement region of the patterned plated layer used for measurement to thereby calculate the deposited amount of the plating catalyst or the precursor thereof.

[Electroconductive Laminate]

The electroconductive laminate of the present invention includes a base material, a patterned plated layer containing a portion having a line width of less than 3 μm and disposed on the base material, and a metal layer disposed on the patterned plated layer, in which a plating catalyst is deposited on the patterned plated layer, and the deposited amount of the plating catalyst in the patterned plated layer is 50 mg/m² or more.

The electroconductive laminate of the present invention is obtained by using the above-described method for producing an electroconductive laminate. Therefore, in the case where the laminate of the present invention is used, a metal layer having low resistance can be formed at a position corresponding to the patterned plated layer.

The details of the base material, the patterned plated layer, the plating catalyst, and the metal layer included in the electroconductive laminate of the present invention are the same as described in the method for producing an electroconductive laminate, so that the description thereof will be omitted.

Since the electroconductive laminate of the present invention is obtained by the above-described method, the deposited amount of the plating catalyst or the precursor thereof becomes a high value of 50 mg/m² or more. Accordingly, initial uniformity of plating (uniform formation of the metal layer on the plated layer at the beginning of the metal layer forming step) is improved, and as a result, conduction can be secured even in a state in which the thickness of the plating film is thin, so that a fine wiring with good conduction is formed.

In the electroconductive laminate of the present invention, the deposited amount of the plating catalyst is 50 mg/m² or more and preferably 50 to 1,000 mg/m².

The method for measuring the deposited amount of the plating catalyst or the precursor thereof is as described above.

### EXAMPLES

Hereinafter, the present invention will be described in detail with reference to Examples. However, the present invention is not limited thereto.

### Example 1

The electroconductive laminate (electroconductive film) of Example 1 was produced in the following manner. A primer layer forming composition and a plated layer forming composition 1 prepared as described below were used in producing the electroconductive film of Example 1.

[Preparation of Primer Layer Forming Composition]

A liquid obtained by dissolving 100 g of hydrogenated nitrile butadiene rubber (trade name “Zetpol 0020”, manufactured by Zeon Corporation) in 900 g of cyclopentanone (manufactured by Tokyo Chemical Industry Co., Ltd.) was used as a primer layer forming composition.

[Preparation of Plated Layer Forming Composition 1]

Polyacrylic acid (manufactured by Wako Pure Chemical Industries, Ltd., weight-average molecular weight: 80,000 to 150,000), tetrafunctional acrylamide (compound in which “R's” in Formula (A) are all methyl groups), a polymerization initiator (trade name “IRGACURE 127”, a photopolymerization initiator, manufactured by BASF Corporation), a fluorine-based surfactant (trade name “W-AHE”, manufactured by FUJIFILM Corporation), and isopropanol were prepared so as to have the following ratios to obtain a plated layer forming composition 1 (hereinafter, also simply referred to as “Composition 1”).

(Composition of Composition 1)

| | |
|---|---|
| Polyacrylic acid | 1.35% by mass |
| Tetrafunctional acrylamide | 0.9% by mass |
| Polymerization initiator | 0.045% by mass |
| Fluorine-based surfactant | 0.015% by mass |
| Isopropanol | 97.69% by mass |

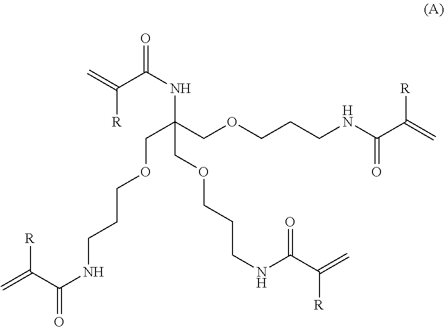

[Production of Electroconductive Film of Example 1]

(Preparation of Base Material)

The primer layer forming composition was applied onto a support (trade name “LUMIRROR U48”, polyethylene terephthalate film, long film, manufactured by Toray Industries, Inc.) using a bar coater, a film was formed to have a film thickness of 600 nm, and the film was dried through an oven at 120° C. to obtain a base material on which a primer layer was formed on the support.

In the case where the obtained base material was dyed under the following conditions, no dyeing was visually observed. Specifically, in the case where the absorbance of the base material before and after dyeing was measured, it was found that the difference in absorbance at a wavelength of 525 nm before and after dyeing was 0.03 or less, and the alkali resistance of the obtained base material was excellent. For the measurement of absorbance, a spectrophotometer V-670 (trade name, manufactured by JASCO Corporation) was used.

(Plated Layer Forming Step)

Subsequently, Composition 1 was applied onto the primer layer using a bar coater, a film was formed to have a film thickness of 300 nm, and the film was dried through an oven at 80° C. to form a plated layer forming layer on the base material. In this manner, the base material on which the plated layer forming layer was formed (base material with a plated layer forming layer) was produced.

(Patterned Plated Layer Forming Step)

Thereafter, the base material with a plated layer forming layer was placed in a vacuum chamber, and a photo mask (hard mask) having opening portions of linear thin wire mesh pattern of 1 μm in width (thin wire width of opening portion: 1 μm, pitch of opening portion: 150 μm, intersecting angle of thin wires: 90°) and the plated layer forming layer were brought into close contact with each other in a vacuum state. Subsequently, with the vacuum state, the plated layer forming layer was irradiated with light having a wavelength of 254 nm at an irradiation dose of 7,200 mJ/cm² using a parallel light exposure machine. Thereafter, development was carried out using warm water at 50° C. to remove the unexposed portion of the plated layer forming layer, thereby forming a patterned plated layer constituted of the exposed portion. The thickness of the patterned plated layer after the exposure-development obtained in this manner was 0.3 μm.

In Example 1, it was possible to form thin wires of the patterned plated layer having a width of 1.3 μm by using a photo mask having opening portions of linear thin wire mesh pattern of 1 μm in width. In this manner, it was possible to form a patterned plated layer with high accuracy. In addition, sticking of the plated layer forming layer to the photo mask was not confirmed.

(Plating Catalyst Applying Step)

Thereafter, the patterned plated layer was washed with water and immersed in an alkaline ionic Pd catalyst-applying liquid (ALCUP Activator MAT-2-A+MAT-2-B manufactured by C. Uyemura & Co., Ltd.) for 5 minutes. The “ionic” in the alkaline ionic Pd catalyst-applying liquid means that Pd exists as a metal ion in the catalyst-applying liquid. The pH of the alkaline ionic Pd catalyst-applying liquid was measured with a pH meter F-74 (trade name, manufactured by Horiba, Ltd.), which was 11.

Thereafter, the patterned plated layer was washed with water, and the patterned plated layer after washing with water was immersed in a plating catalyst-reducing liquid (manufactured by Rohm and Haas Company).

(Metal Layer Forming Step)

Subsequently, the patterned plated layer was washed with water and immersed in a copper plating liquid (CU-510, manufactured by MacDermid Corporation, containing ethylenediamine tetraacetic acid) at 30° C., and an electroless copper plating treatment was carried out so that the plating copper thin wire width (line width of the metal layer) was 3.5 μm.

In this manner, an electroconductive film of Example 1 in which copper plating was applied on the patterned plated layer (on which a metal layer was formed) was obtained. The metal layer was a mesh-like thin wire pattern like the patterned plated layer.

### Example 2

An electroconductive film of Example 2 was produced in the same manner as in Example 1, except that a plated layer forming composition 2 prepared by the following procedure (hereinafter, simply referred to as “Composition 2”) was used in place of Composition 1.

### Synthesis Example 1: Polymer 1

1 L of ethyl acetate and 159 g of 2-aminoethanol were charged into a 2 L three-neck flask which was then cooled in an ice bath. The internal temperature of the system was adjusted to 20□C or lower, and 150 g of 2-bromoisobutyrate bromide was added dropwise thereto. Then, the internal temperature was elevated to room temperature (25□C), followed by reaction for 2 hours. After the reaction was completed, 300 mL of distilled water was added to stop the reaction. Thereafter, the ethyl acetate phase was washed 4 times with 300 mL of distilled water and dried over magnesium sulfate, and ethyl acetate was further distilled off to obtain 80 g of a raw material A.

Next, 47.4 g of raw material A, 22 g of pyridine, and 150 mL of ethyl acetate were charged into a 500 mL three-neck flask which was then cooled in an ice bath. The internal temperature of the system was adjusted to 20□C or lower, and 25 g of acrylic acid chloride was added dropwise thereto. Then, the temperature was elevated to room temperature, followed by reaction for 3 hours. After the reaction was completed, 300 mL of distilled water was added to stop the reaction. Thereafter, the ethyl acetate phase was washed 4 times with 300 mL of distilled water and dried over magnesium sulfate, and ethyl acetate was further distilled off. Then, column chromatography was carried out to obtain the following monomer M1 (20 g).

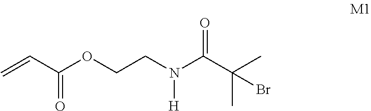

8 g of N,N-dimethylacetamide was charged into a 500 mL three-neck flask which was then heated to 65° C. under a nitrogen stream. A solution of 14.3 g of monomer M1, 3.0 g of acrylonitrile (manufactured by Tokyo Chemical Industry Co., Ltd.), 6.5 g of acrylic acid (manufactured by Tokyo Chemical Industry Co., Ltd.), and 0.4 g of V-65 (manufactured by Wako Pure Chemical Industries, Ltd.) in 8 g of N,N-dimethylacetamide was added dropwise thereto over 4 hours.

After the dropwise addition was completed, the reaction solution was further stirred for three hours. Then, 41 g of N,N-dimethylacetamide was added, and the reaction solution was cooled to room temperature. 0.09 g of 4-hydroxy TEMPO (4-hydroxy-2,2,6,6-tetramethylpiperidine 1-oxyl, manufactured by Tokyo Chemical Industry Co., Ltd.), and 54.8 g of diazabicycloundecene (DBU) were added to the above reaction solution, followed by reaction at room temperature for 12 hours to obtain a reaction liquid. Thereafter, 54 g of a 70% by mass aqueous methanesulfonic acid solution was added to the reaction liquid. After the reaction was completed, re-precipitation was carried out with water and the solids were taken out to obtain 12 g of the following polymer 1 (Formula (P1)).

Identification of the resulting polymer 1 was carried out using an infrared spectroscopy (IR) measuring instrument (manufactured by Horiba Ltd.). The measurement was carried out by dissolving a polymer in acetone and using KBr crystals. As a result of IR measurement, a peak was observed near 2240 cm⁻¹ and therefore it was found that acrylonitrile, which is a nitrile unit, has been introduced into the polymer. Further, it was found through an acid value measurement that acrylic acid has been introduced as a carboxyl group unit.

In addition, the polymer 1 was dissolved in heavy dimethyl sulfoxide (DMSO), followed by measurement with a 300 MHz ¹H nuclear magnetic resonance (NMR) spectrometer (AV-300, manufactured by Bruker Co., Ltd.). As a result, a peak corresponding to the nitrile group-containing unit was broadly observed in 2.5-0.7 ppm (5H fraction), a peak corresponding to the polymerizable group-containing unit was broadly observed in 7.8-8.1 ppm (1H fraction), 5.8-5.6 ppm (1H fraction), 5.4-5.2 ppm (1H fraction), 4.2-3.9 ppm (2H fraction), 3.3-3.5 ppm (2H fraction), and 2.5-0.7 ppm (6H fraction), a peak corresponding to the carboxy group-containing unit was broadly observed in 2.5-0.7 ppm (3H fraction), and the polymerizable group-containing unit:nitrile group-containing unit:carboxy group unit was found to be 30:30:40 (mol %).

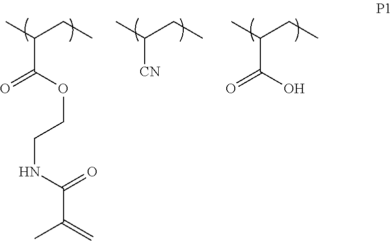

(Preparation of Composition 2)

5.142 g of water, 67.110 g of propylene glycol monomethyl ether, 0.153 g of 2-acrylamide-2-methylpropanesulfonic acid, 17.034 g of Polymer 1, 0.279 g of hexamethylene bisacrylamide, and 0.279 g of IRGACURE OXE127 (BASF Corporation) were added to a 200 ml beaker equipped with a magnetic stirrer to obtain Composition 2.

### Production of Electroconductive Film of Example 2

(Plated Layer Forming Step)

The Composition 2 was applied onto the primer layer of the base material obtained in the same manner as in Example 1 using a bar coater, a film was formed so as to have a film thickness of 0.8 μm, and the film was dried through an oven at 80° C. to form a plated layer forming layer on the base material. In this manner, a base material on which a plated layer forming layer was formed (base material with a plated layer forming layer) was produced.

(Patterned Plated Layer Forming Step)

Subsequently, a patterned plated layer was formed in the same manner as in Example 1. The thickness of the patterned plated layer after the exposure-development obtained in this manner was 0.8 μm.

In Example 2, it was possible to form thin wires of the patterned plated layer having a width of 1.5 μm by using a photo mask having opening portions of linear thin wire mesh pattern of 1 μm in width (a photo mask similar to that of Example 1). In this manner, according to the production method of Example 2, it was possible to form a patterned plated layer with high accuracy. In addition, sticking of the plated layer forming layer to the photo mask was not confirmed.

For the subsequent steps, the electroconductive film of Example 2 was produced in the same manner as in Example 1.

### Example 3

An electroconductive film of Example 3 was produced in the same manner as in Example 1, except that the film thickness of the plated layer was changed to 0.8 μm in place of 0.3 μm.

In Example 3, it was possible to form thin wires of the patterned plated layer having a width of 1.5 μm by using a photo mask having opening portions of linear thin wire mesh pattern of 1 μm in width (a photo mask similar to that of Example 1). In this manner, according to the production method of Example 3, it was possible to form a patterned plated layer with high accuracy. In addition, sticking of the plated layer forming layer to the photo mask was not confirmed.

### Example 4

An electroconductive film of Example 4 was produced in the same manner as in Example 1, except that TOYOBO A4300 (trade name, manufactured by Toyobo Co., Ltd., polyester film) was used as a support in place of LUMIRROR U48 and no primer layer was formed.

In Example 4, it was possible to form thin wires of the patterned plated layer having a width of 1.3 μm by using a photo mask having opening portions of linear thin wire mesh pattern of 1 μm in width (a photo mask similar to that of Example 1). In this manner, according to the production method of Example 4, it was possible to form a patterned plated layer with high accuracy. In addition, sticking of the plated layer forming layer to the photo mask was not confirmed.

In the case where the base material (TOYOBO A4300) was dyed under the above-mentioned conditions, slight dyeing of the base material was visually observed. Specifically, the absorbance of the base material (TOYOBO A4300) before and after dyeing was measured, and the difference in absorbance at a wavelength of 525 nm before and after dyeing was 0.05. For the measurement of absorbance, a spectrophotometer V-670 (trade name, manufactured by JASCO Corporation) was used.

### Comparative Example 1

An electroconductive film of Comparative Example 1 was produced in the same manner as in Example 1, except that THRU-CUP PEA (manufactured by C. Uyemura & Co., Ltd., Rochelle salt-based electroless plating liquid, not containing both aminocarboxylic acid and aminocarboxylic acid salt) was used as an electroless copper plating liquid in place of CU-510 (manufactured by MacDermid Corporation).

### Comparative Example 2

An electroconductive film of Comparative Example 2 was produced in the same manner as in Example 1, except that, in the plating catalyst applying step, an acidic (pH=4) ionic Pd catalyst-applying liquid (manufactured by Rohm and Haas Company) was used in place of the alkaline ionic Pd catalyst-applying liquid (ALCUP Activator MAT-2-A+MAT-2-B, manufactured by C. Uyemura & Co., Ltd.).

### Comparative Example 3

An electroconductive film of Comparative Example 3 was produced in the same manner as in Example 1, except that the thin wire width of the opening portion of the photo mask was changed to 3 μm in place of 1 μm (the pitch of thin wires and the intersecting angle of thin wires were the same as in Example 1).

[Evaluation Test]

[Pattern Formation State]

Observation was carried out using an optical microscope (trade name “MX 80”, manufactured by Olympus Corporation), and the surfaces of the electroconductive films of Examples and Comparative Examples were observed, and the pattern formation state was evaluated according to the following standards.

A: A metal layer is formed at a position corresponding to the patterned plated layer, and adjacent wiring patterns constituting the metal layer are not connected to each other.

B: A metal layer is formed at a position corresponding to the patterned plated layer, and adjacent wiring patterns constituting the metal layer are not connected to each other, but the pattern intersecting portion is enlarged.

C: A metal layer is formed at a center of a position corresponding to the patterned plated layer, and a portion where adjacent wiring patterns constituting the metal layer are connected to each other can be seen.

[Conductivity and Relative Resistance]

Regarding the electroconductive films of Examples and Comparative Examples, a region of 3 mm in length×10 mm in width of a metal layer formed on a mesh-like patterned plated layer (that is, a mesh-like wiring pattern) was defined as a mesh region. In addition, a 3 mm square portion at both ends in the lateral direction in the mesh region was defined as a pad region.

Then, the tester was brought into contact with the pad region, and the conductivity and the resistivity were measured.

The conductivity was evaluated 10 times for each of the electroconductive films of Examples and Comparative Examples, and counting the number of times that conduction was observed was carried out. The evaluation standards of the conductivity are “A” for which conduction of 8 times or more was observed, “B” for which conduction of 3 to 7 times was observed, and “C” for which conduction of twice or less was observed.

The evaluation of the relative resistance was carried out by measuring the resistivity of each of the electroconductive films of Examples and Comparative Examples and then calculating the relative resistance of each of the electroconductive films of Examples and Comparative Examples with the resistivity of Example 1 being 1.

[Evaluation Results]

The results of the evaluation tests are shown in Table 1.

TABLE 1

| | Base material (primer | | Plated layer forming layer | | | | |
|---|---|---|---|---|---|---|---|
| | layer) | | | | Interactive | Patterned plated layer | |
| | | Presence | | Polymerizable | group in | Line width | Thickness |
| | | or | Type of plated | group in plated | plated layer | (μm) of | (μm) of |
| | | absence of | layer forming | layer forming | forming | patterned | patterned |
| | Type | dyeability | composition | composition | composition | plated layer | plated layer |
| Example 1 | Zetpol 0020 | Absent | Composition 1 | Methacrylamide | Carboxy | 1.3 | 0.3 |
| | | | | group | group | | |
| Example 2 | Zetpol 0020 | Absent | Composition 2 | Methacrylamide | Carboxy | 1.5 | 0.8 |
| | | | | group | group | | |
| Example 3 | Zetpol 0020 | Absent | Composition 1 | Methacrylamide | Carboxy | 1.5 | 0.8 |
| | | | | group | group | | |
| Example 4 | A4300 | Present | Composition 1 | Methacrylamide | Carboxy | 1.3 | 0.3 |
| | | | | group | group | | |
| Comparative | Zetpol 0020 | Absent | Composition 1 | Methacrylamide | Carboxy | 1.3 | 0.3 |
| Example 1 | | | | group | group | | |
| Comparative | Zetpol 0020 | Absent | Composition 1 | Methacrylamide | Carboxy | 1.3 | 0.3 |
| Example 2 | | | | group | group | | |
| Comparative | Zetpol 0020 | Absent | Composition 1 | Methacrylamide | Carboxy | 3 | 0.3 |
| Example 3 | | | | group | group | | |

| | Plating catalyst | | | | | |
|---|---|---|---|---|---|---|
| | layer | Metal layer | | Evaluation results | | |
| | Type of plating | | Line width | Pattern | | |
| | catalyst-applying | | (μm) of | formation | | Relative |
| | liquid | Type of plating liquid | metal layer | state | Conductivity | resistance |
| Example 1 | Alkaline ionic Pd | Ethylenediaminetetraacetic | 3.5 | A | A | 1 |
| | catalyst-applying | acid | | | | |
| | liquid | CU-510 | | | | |
| Example 2 | Alkaline ionic Pd | Ethylenediaminetetraacetic | 3.5 | A | A | 1.5 |
| | catalyst-applying | acid | | | | |
| | liquid | CU-510 | | | | |
| Example 3 | Alkaline ionic Pd | Ethylenediaminetetraacetic | 3.5 | A | A | 1.3 |
| | catalyst-applying | acid | | | | |
| | liquid | CU-510 | | | | |
| Example 4 | Alkaline ionic Pd | Ethylenediaminetetraacetic | 3.5 | B | B | 2 |
| | catalyst-applying | acid | | | | |
| | liquid | CU-510 | | | | |
| Comparative | Alkaline ionic Pd | THRU-CUP PEA | Abnormally | C | — | — |
| Example 1 | catalyst-applying | (Rochelle salt-based) | deposited | | | |
| | liquid | | | | | |
| Comparative | Alkaline ionic Pd | Ethylenediaminetetraacetic | 3.5 | A | B | 4 |
| Example 2 | catalyst-applying | acid | | | | |
| | liquid | CU-510 | | | | |
| Comparative | Alkaline ionic Pd | Ethylenediaminetetraacetic | 3.5 | A | C | — |
| Example 3 | catalyst-applying | acid | | | | |
| | liquid | CU-510 | | | | |

As shown in the evaluation results of Table 1, it was found that, by forming a patterned plated layer containing a portion with a line width of less than 3 μm and using an alkaline plating catalyst-applying liquid and a plating liquid containing predetermined components, a metal layer having low resistance can be formed at a position corresponding to the patterned plated layer (Examples).

On the other hand, from the evaluation results of Comparative Example 1, it was found that, in the case where a plating liquid not containing an aminocarboxylic acid and an aminocarboxylic acid salt is used, the metal is abnormally deposited and therefore the metal layer is also formed at a position other than the position corresponding to the patterned plated layer. Since the metal was abnormally deposited, the conductivity and the relative resistance were not evaluated.

Further, from the evaluation results of Comparative Example 2, it was found that, in the case where an acidic plating catalyst-applying liquid is used, the resistance of the metal layer becomes too high.

From the evaluation results of Comparative Example 3, it was found that, in the case where a patterned plated layer having a line width of 3 μm or more is formed, the conductivity is inferior (that is, the resistance is high). In addition, the relative resistance was not evaluated.

With respect to the electroconductive films of Examples 1 to 4 and Comparative Example 2, the amount of the Pd catalyst deposited on the patterned plated layer forming layer was measured with a glow discharge optical emission spectrometer (trade name “GD-Profiler 2”, manufactured by Horiba Ltd).

As a result, in each of Examples 1 to 4, the amount of Pd catalyst deposited on the patterned plated layer forming layer was 50 mg/m² or more.

With respect to Comparative Example 2, the amount of Pd catalyst deposited on the patterned plated layer forming layer was 25 mg/m².

### EXPLANATION OF REFERENCES

12: base material
14: plated layer forming layer
14a: exposed region (exposed portion)
14b: unexposed region (unexposed portion)
14A: patterned plated layer
20: plating catalyst layer
22: detection electrode
24: lead-out wiring
25: metal layer
30: electroconductive laminate
50: mask
52: opening portion

What is claimed is:

1. A method for producing an electroconductive laminate having a base material, a patterned plated layer, and a metal layer, the method comprising:
a step of forming a plated layer forming layer on the base material using a plated layer forming composition containing a polymerization initiator and Compound X or Composition Y below;
a step of subjecting the plated layer forming layer to a patternwise exposure treatment and then subjecting the exposed plated layer forming layer to a development treatment to form the patterned plated layer containing a portion having a line width of less than 3 μm;
a step of applying a plating catalyst or a precursor thereof to the patterned plated layer using an alkaline plating catalyst-applying liquid containing the plating catalyst or the precursor thereof; and
a step of subjecting the patterned plated layer to which the plating catalyst or the precursor thereof has been applied to a plating treatment using a plating liquid containing at least one of an aminocarboxylic acid or an aminocarboxylic acid salt to form the metal layer on the patterned plated layer.
Compound X: a compound having a functional group capable of interacting with a plating catalyst or a precursor thereof, and a polymerizable group
Composition Y: a composition containing a compound having a functional group capable of interacting with a plating catalyst or a precursor thereof, and a compound having a polymerizable group

2. The method for producing an electroconductive laminate according to claim 1, wherein the plating catalyst or the precursor thereof in the plating catalyst-applying liquid is a metal ion.

3. The method for producing an electroconductive laminate according to claim 1, wherein the interacting functional group is an ionic polar group.

4. The method for producing an electroconductive laminate according to claim 1, wherein the polymerizable group is selected from the group consisting of an acrylamide group and a methacrylamide group.

5. The method for producing an electroconductive laminate according to claim 1, wherein, in the case where the base material is dyed under the dyeing conditions below, a change in absorbance of the base material at a wavelength of 525 nm before and after dyeing is within 0.05.
Dyeing conditions: the base material is immersed in a 0.1 M sodium hydroxide aqueous solution at 30° C. for 5 minutes, and then the base material is taken out and is immersed in a 1% by mass rhodamine 6G aqueous solution for 1 minute

6. The method for producing an electroconductive laminate according to claim 1, wherein the electroconductive laminate is used for a touch panel sensor.

7. The method for producing an electroconductive laminate according to claim 2, wherein the interacting functional group is an ionic polar group.

8. The method for producing an electroconductive laminate according to claim 2, wherein the polymerizable group is selected from the group consisting of an acrylamide group and a methacrylamide group.

9. The method for producing an electroconductive laminate according to claim 3, wherein the polymerizable group is selected from the group consisting of an acrylamide group and a methacrylamide group.

10. The method for producing an electroconductive laminate according to claim 7, wherein the polymerizable group is selected from the group consisting of an acrylamide group and a methacrylamide group.

11. The method for producing an electroconductive laminate according to claim 2, wherein, in the case where the base material is dyed under the dyeing conditions below, a change in absorbance of the base material at a wavelength of 525 nm before and after dyeing is within 0.05.
Dyeing conditions: the base material is immersed in a 0.1 M sodium hydroxide aqueous solution at 30° C. for 5 minutes, and then the base material is taken out and is immersed in a 1% by mass rhodamine 6G aqueous solution for 1 minute

12. The method for producing an electroconductive laminate according to claim 3, wherein, in the case where the base material is dyed under the dyeing conditions below, a change in absorbance of the base material at a wavelength of 525 nm before and after dyeing is within 0.05.
Dyeing conditions: the base material is immersed in a 0.1 M sodium hydroxide aqueous solution at 30° C. for 5 minutes, and then the base material is taken out and is immersed in a 1% by mass rhodamine 6G aqueous solution for 1 minute

13. The method for producing an electroconductive laminate according to claim 4, wherein, in the case where the base material is dyed under the dyeing conditions below, a change in absorbance of the base material at a wavelength of 525 nm before and after dyeing is within 0.05.
Dyeing conditions: the base material is immersed in a 0.1 M sodium hydroxide aqueous solution at 30° C. for 5 minutes, and then the base material is taken out and is immersed in a 1% by mass rhodamine 6G aqueous solution for 1 minute

14. The method for producing an electroconductive laminate according to claim 7, wherein, in the case where the base material is dyed under the dyeing conditions below, a change in absorbance of the base material at a wavelength of 525 nm before and after dyeing is within 0.05.
Dyeing conditions: the base material is immersed in a 0.1 M sodium hydroxide aqueous solution at 30° C. for 5 minutes, and then the base material is taken out and is immersed in a 1% by mass rhodamine 6G aqueous solution for 1 minute

15. The method for producing an electroconductive laminate according to claim 8, wherein, in the case where the base material is dyed under the dyeing conditions below, a change in absorbance of the base material at a wavelength of 525 nm before and after dyeing is within 0.05.
Dyeing conditions: the base material is immersed in a 0.1 M sodium hydroxide aqueous solution at 30° C. for 5 minutes, and then the base material is taken out and is immersed in a 1% by mass rhodamine 6G aqueous solution for 1 minute

16. The method for producing an electroconductive laminate according to claim 9, wherein, in the case where the base material is dyed under the dyeing conditions below, a change in absorbance of the base material at a wavelength of 525 nm before and after dyeing is within 0.05.
Dyeing conditions: the base material is immersed in a 0.1 M sodium hydroxide aqueous solution at 30° C. for 5 minutes, and then the base material is taken out and is immersed in a 1% by mass rhodamine 6G aqueous solution for 1 minute

17. The method for producing an electroconductive laminate according to claim 10, wherein, in the case where the base material is dyed under the dyeing conditions below, a change in absorbance of the base material at a wavelength of 525 nm before and after dyeing is within 0.05.
Dyeing conditions: the base material is immersed in a 0.1 M sodium hydroxide aqueous solution at 30° C. for 5 minutes, and then the base material is taken out and is immersed in a 1% by mass rhodamine 6G aqueous solution for 1 minute

18. The method for producing an electroconductive laminate according to claim 2, wherein the electroconductive laminate is used for a touch panel sensor.

19. The method for producing an electroconductive laminate according to claim 3, wherein the electroconductive laminate is used for a touch panel sensor.

20. The method for producing an electroconductive laminate according to claim 4, wherein the electroconductive laminate is used for a touch panel sensor.
